(19) United States
(12) Patent Application Publication
(10) Pub. No.: US 2026/0024558 A1
(43) Pub. Date: Jan. 22, 2026

(54) SEMICONDUCTOR MEMORY DEVICE

(71) Applicant: Kioxia Corporation, Tokyo (JP)

(72) Inventor: Shinya ARAI, Yokkaichi (JP)

(73) Assignee: Kioxia Corporation, Tokyo (JP)

(21) Appl. No.: 19/058,097

(22) Filed: Feb. 20, 2025

(30) Foreign Application Priority Data
Jul. 16, 2024 (JP) 2024-113155

(51) Int. Cl. G11C 5/06; G11C 16/04; H01L 23/00; H01L 25/065; H10B 43/10; H10B 43/35; H10B 80/00

(52) U.S. Cl. CPC G11C 5/063; G11C 16/0483; H01L 24/08; H01L 25/0657; H10B 43/10; H10B 43/35; H10B 80/00; H01L 2224/08245; H01L 2225/06524

(57) ABSTRACT

According to one embodiment, a semiconductor memory device includes a first chip; and a second chip electrically connected to the first chip via a first connection pad, the second chip including a memory cell array, a first contact electrically connected to the first connection pad, and a first interconnect including a first coupling portion electrically connected to an upper end of the first contact, and a first extension continuously extending from the first coupling portion above an upper surface of the source line, wherein the first coupling portion has a shape in which a trench above the first contact is filled up to a level of a lower surface of the first extension, and the first coupling portion includes a lower surface at a level below the upper surface of the source line.

### CROSS-REFERENCE TO RELATED APPLICATION(S)

This application is based upon and claims the benefit of priority from Japanese Patent Application No. 2024-113155, filed Jul. 16, 2024, the entire contents of which are incorporated herein by reference.

### FIELD

Embodiments described herein relate generally to a semiconductor memory device.

### BACKGROUND

As a semiconductor memory device capable of storing data in a nonvolatile manner, a NAND flash memory is known. A NAND flash memory adopts a three-dimensional memory structure for enhanced integration and increased capacity.

### BRIEF DESCRIPTION OF THE DRAWINGS

FIG. 1 is a block diagram showing an exemplary configuration of a memory system including a semiconductor memory device according to an embodiment.

FIG. 2 is a circuit diagram showing an exemplary circuit configuration of a memory cell array in the semiconductor memory device according to the embodiment.

FIG. 3 is a plan view showing an exemplary planar layout of the semiconductor memory device according to the embodiment.

FIG. 4 is a plan view showing an exemplary planar layout of the memory cell array in the semiconductor memory device according to the embodiment.

FIG. 5 is a plan view showing an exemplary planar layout of the memory cell array in the semiconductor memory device according to the embodiment.

FIG. 6 is a sectional view taken along the line VI-VI indicated in FIG. 5 and shows an exemplary sectional structure of the memory cell array in the semiconductor memory device according to the embodiment.

FIG. 7 is a sectional view taken along the line VII-VII indicated in FIG. 6 and shows an exemplary sectional structure of a memory pillar in the semiconductor memory device according to the embodiment.

FIG. 8 is a sectional view showing an exemplary sectional structure of a circuit region in the semiconductor memory device according to the embodiment.

FIG. 9 is a sectional view showing exemplary coupling portions, one between an interconnect layer and a source line and one between the interconnect layer and a contact, in the semiconductor memory device according to the embodiment.

FIG. 10 is a sectional view taken along the line X-X indicated in FIG. 8 and shows exemplary coupling portions between the interconnect layer and the respective contacts in the semiconductor memory device according to the embodiment.

FIG. 11 is a sectional view showing an exemplary sectional structure of connection pads in the semiconductor memory device according to the embodiment.

FIG. 12 is a sectional view for explaining an exemplary method for manufacturing the semiconductor memory device according to the embodiment.

FIG. 13 is a sectional view for explaining the exemplary method for manufacturing the semiconductor memory device according to the embodiment.

FIG. 14 is a sectional view for explaining the exemplary method for manufacturing the semiconductor memory device according to the embodiment.

FIG. 15 is a sectional view for explaining the exemplary method for manufacturing the semiconductor memory device according to the embodiment.

FIG. 16 is a sectional view for explaining the exemplary method for manufacturing the semiconductor memory device according to the embodiment.

FIG. 17 is a sectional view for explaining the exemplary method for manufacturing the semiconductor memory device according to the embodiment.

FIG. 18 is a sectional view for explaining the exemplary method for manufacturing the semiconductor memory device according to the embodiment.

FIG. 19 is a sectional view showing an exemplary sectional structure of a circuit region in a semiconductor memory device according to a first modification.

FIG. 20 is a sectional view for explaining an exemplary method for manufacturing the semiconductor memory device according to the first modification.

FIG. 21 is a sectional view for explaining the exemplary method for manufacturing the semiconductor memory device according to the first modification.

FIG. 22 is a sectional view for explaining the exemplary method for manufacturing the semiconductor memory device according to the first modification.

FIG. 23 is a sectional view for explaining the exemplary method for manufacturing the semiconductor memory device according to the first modification.

FIG. 24 is a sectional view for explaining the exemplary method for manufacturing the semiconductor memory device according to the first modification.

FIG. 25 is a sectional view showing exemplary coupling portions between an interconnect layer and respective contacts in a semiconductor memory device according to a second modification.

FIG. 26 is a sectional view showing an exemplary sectional structure of a circuit region in a semiconductor memory device according to a third modification.

### DETAILED DESCRIPTION

In general, according to one embodiment, a semiconductor memory device includes a first chip including a substrate defining a first region and a second region; and a second chip contacting the first chip in a first direction crossing a surface of the substrate, the second chip being electrically connected to the first chip via a first connection pad at a boundary region between the first chip and the second chip, the second chip including a memory cell array in the first region, the memory cell array including a source line, a plurality of word lines mutually separated in the first direction below the source line, and a memory pillar extending in the first direction, crossing the word lines, and including an upper end coupled to the source line, a first contact in the second region, the first contact extending in the first direction and electrically connected to the first connection pad, and a first interconnect including a first coupling portion for electrical connection with an upper end of the first contact, and a first extension continuously extending in a second direction crossing the first direction from an upper end of the first coupling portion and above an upper surface of the source line, wherein the first coupling portion has a shape in which a trench above the first contact in the first direction is filled up to a level of a lower surface of the first extension in the first direction, and the first coupling portion includes a lower surface at a level below the upper surface of the source line in the first direction.

Embodiments will be described with reference to the drawings. The drawings use dimensions, ratios, etc., which may not necessarily conform to actual products. The description will use the same reference signs for the elements or components having the same or substantially the same functions and configurations. To distinguish between elements having the same or substantially the same configurations, the description may add mutually different characters or numerals after their respective reference signs.

### 1 Embodiments

A semiconductor memory device 1 according to one or more embodiments will be described.

### 1.1 Configurations

Configurations for the semiconductor memory device 1 according to one or more embodiments will be described.

### 1.1.1 Memory System

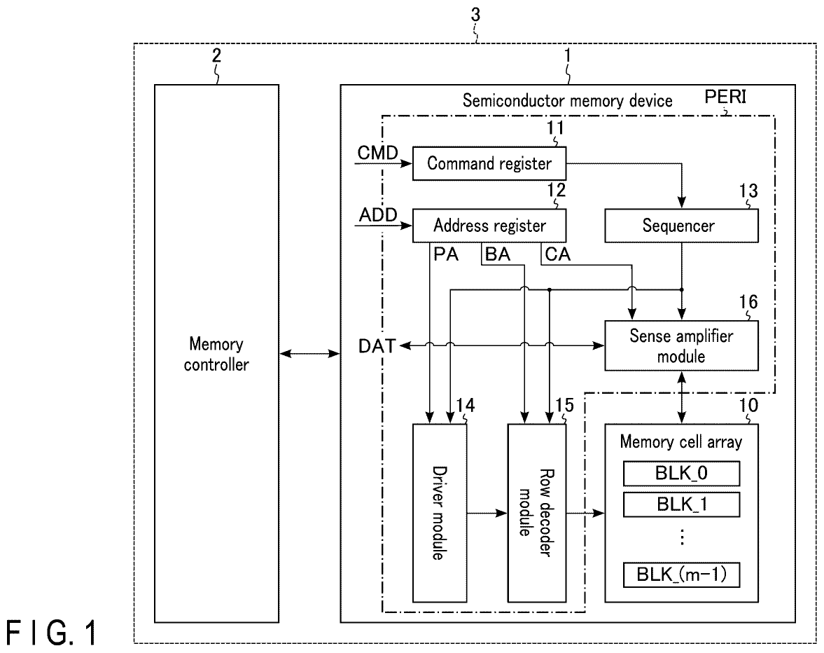

The description starts with an exemplary configuration of a memory system 3 by referring to FIG. 1. FIG. 1 is a block diagram showing an exemplary configuration of the memory system 3 including the semiconductor memory device 1 according to an embodiment.

The memory system 3 may be, for example, a solid state drive (SSD), an SD™ card, or the like. In one example, the memory system 3 is adapted to be coupled to an external host device (not shown in the figure). The memory system 3 stores data from the host device. The memory system 3 also reads out data to the host device.

The memory system 3 includes the semiconductor memory device 1 and a memory controller 2.

The semiconductor memory device 1 may be, for example, a NAND flash memory. The semiconductor memory device 1 stores data in a nonvolatile manner. The description will assume instances where the semiconductor memory device 1 is a NAND flash memory.

The memory controller 2 is constituted by, for example, an integrated circuit such as a system-on-a-chip (SoC). The memory controller 2 writes data in the semiconductor memory device 1 based on, for example, a request from the host device. Also, the memory controller 2 reads data from the semiconductor memory device 1 based on, for example, a request from the host device. The memory controller 2 sends data read from the semiconductor memory device 1 to the host device.

Communications between the semiconductor memory device 1 and the memory controller 2 comply with, for example, a single data rate (SDR) interface, a toggle double data rate (DDR) interface, an open NAND flash interface (ONFI), etc.

### 1.1.2 Semiconductor Memory Device

Referring to the same FIG. 1, an internal configuration of the semiconductor memory device 1 will be described. In one example, the semiconductor memory device 1 includes a memory cell array 10 and a peripheral circuit PERI. In one example, the peripheral circuit PERI includes a command register 11, an address register 12, a sequencer 13, a driver module 14, a row decoder module 15, and a sense amplifier module 16.

The memory cell array 10 includes multiple blocks BLK0 to BLK(m−1), where m is an integer equal to or greater than 2. Each block BLK is a set of multiple memory cells capable of storing data in a nonvolatile manner. In one example, each block BLK is used as a unit for data erasure. The memory cell array 10 is provided with multiple bit lines and multiple word lines. In one example, each memory cell is associated with one bit line and one word line.

The command register 11 holds a command CMD received by the semiconductor memory device 1 from the memory controller 2. Examples of the command CMD include instructions to cause the sequencer 13 to conduct read, write, and erase operations, etc.

The address register 12 holds address information ADD received by the semiconductor memory device 1 from the memory controller 2. The address information ADD includes, for example, a page address PA, a block address BA, and a column address CA. The page address PA, the block address BA, and the column address CA in exemplary operations are used to select a word line, a block BLK, and a bit line, respectively.

The sequencer 13 takes total control over the operations of the semiconductor memory device 1. The sequencer 13 conducts read, write, and erase operations, etc., according to the command CMD held at the command register 11.

The driver module 14 generates voltages for use in the read, write, and erase operations, etc. For example, the driver module 14 applies the generated voltage to the signal line corresponding to a selected word line based on the page address PA held at the address register 12.

The row decoder module 15, based on the block address BA held at the address register 12, selects a single corresponding block BLK in the memory cell array 10. The row decoder module 15, for example, then transfers the voltage applied to the signal line corresponding to the selected word line to this selected word line in the selected block BLK.

The sense amplifier module 16 in a write operation transfers write data DAT received from the memory controller 2 to the memory cell array 10. Also, the sense amplifier module 16 in a read operation determines data stored in a memory cell based on the voltage of the corresponding bit line. The sense amplifier module 16 transfers the determination result to the memory controller 2 as read data DAT.

### 1.1.3 Circuit Configuration of Memory Cell Array

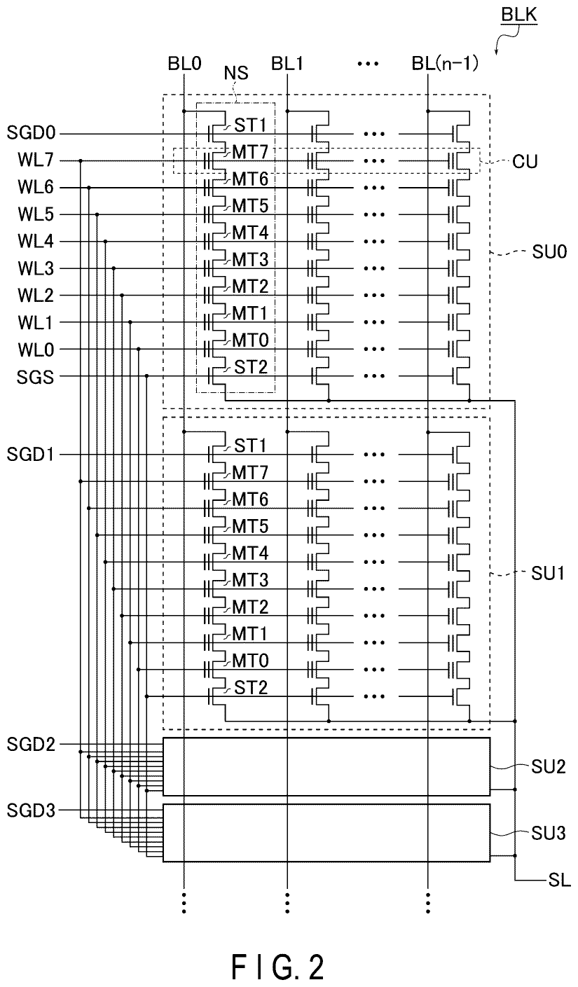

An exemplary circuit configuration of the memory cell array 10 will be described with reference to FIG. 2. FIG. 2 is a circuit diagram showing an exemplary circuit configuration of the memory cell array 10 in the semiconductor memory device 1 according to the embodiment. FIG. 2 shows one of the multiple blocks BLK included in the memory cell array 10. In the example shown in FIG. 2, the block BLK includes four string units SU0, SU1, SU2, and SU3.

Each string unit SU includes multiple NAND strings NS associated with respective bit lines BL0 to BL(n−1), where n is an integer equal to or greater than 2. In one example, the NAND strings NS each include memory cell transistors MT0 to MT7 and select transistors ST1 and ST2. The memory cell transistors MT0 to MT7 each include a control gate and a charge accumulating film. Each of the memory cell transistors MT0 to MT7 stores data in a nonvolatile manner. The select transistors ST1 and ST2 are used for the selection of the string unit SU in various operations. In the description below, each of the bit lines BL0 to BL(n−1) may be simply called a “bit line BL” if the context does not require discriminating the bit lines BL0 to BL(n−1) from one another. Also, each of the memory cell transistors MT0 to MT7 may be simply called a “memory cell MT” if the context does not require discriminating the memory cell transistors MT0 to MT7 from one another.

In each NAND string NS, the memory cell transistors MT0 to MT7 are coupled in series. The select transistor ST1 has its one end coupled to the bit line BL associated with the select transistor ST1. Another end of the select transistor ST1 is coupled to one end of a set of the memory cell transistors MT0 to MT7 coupled in series. The select transistor ST2 has its one end coupled to the other end of the set of the memory cell transistors MT0 to MT7 coupled in series. Another end of the select transistor ST2 is coupled to a source line SL.

In one block BLK, the memory cell transistors MT0 to MT7, with multiple of each provided, have their control gates coupled to respective word lines WL0 to WL7. The multiple select transistors ST1 in each of the string units SU0 to SU3 have their gates coupled to the respective and corresponding one of select gate lines SGD0 to SGD3. On the other hand, the gates of the multiple select transistors ST2 in the same block BLK are coupled to a common select gate line SGS. However, the embodiments are not limited to this, and the gates of the multiple select transistors ST2 may instead be coupled to different select gate lines SGS for the respective string units SU. In the description below, each of the word lines WL0 to WL7 may be simply called a “word line WL” if the context does not require discriminating the word lines WL0 to WL7 from one another. Also, each of the select gate lines SGD0 to SGD3 may be simply called a “select gate line SGD” if the context does not require discriminating the select gate lines SGD0 to SGD3 from one another.

The bit lines BL0 to BL(n−1) are assigned respective column addresses differing from one another. Each bit line BL is shared by the NAND strings NS having the same column address across the multiple blocks BLK. The word lines WL0 to WL7 are provided for each block BLK. In one example, the source line SL is shared by the multiple blocks BLK.

A set of multiple memory cell transistors MT coupled to the common word line WL within one string unit SU may also be called a “cell unit CU”. For example, the storage capacity of a cell unit CU constituted by multiple memory cell transistors MT each adapted to store 1-bit data is defined as “1-page data”. Each cell unit CU may have a storage capacity of 2-page data or more according to the bit number of data to be stored in its memory cell transistors MT.

Note that the circuit configuration of the memory cell array 10 is not limited to the above described configuration. For example, the number of string units SU in each block BLK may be discretionarily set. The numbers of the memory cell transistors MT and the select transistors ST1 and ST2 in each NAND string NS may also be discretionarily set.

### 1.1.4 Structure of Semiconductor Memory Device

An exemplary structure of the semiconductor memory device 1 according to the embodiment will be described.

The description will assume that an X direction is substantially parallel to a semiconductor substrate of the semiconductor memory device 1. The X direction conforms to a direction in which the word lines WL extend. A Y direction is substantially parallel to the semiconductor substrate and is orthogonal to the X direction. The Y direction conforms to a direction in which the bit lines BL extend. A Z1 direction and a Z2 direction are both substantially perpendicular to the semiconductor substrate. The Z1 direction conforms to a direction from the semiconductor substrate of the semiconductor memory device 1 toward an electrode pad. The Z2 direction conforms to a direction from the electrode pad toward the semiconductor substrate. Each of the Z1 direction and the Z2 direction may be simply called a “Z direction” if the context does not require discriminating the Z1 direction and the Z2 direction from one another. In the following description, a side in the Z1 direction with respect to a given element or component may be called “one Z-direction side” (or simply “one side”), and a side in the Z2 direction with respect to a given element or component may be called “the other Z-direction side” (or simply “the other side”). Also, a surface of a given element or component that is located on the electrode pad side may be called a “first surface”, and a surface of a given element or component that is located on the semiconductor substrate side may be called a “second surface”. Such first and second surfaces may also be called “one Z-direction surface” and “the other Z-direction surface”, respectively.

### 1.1.4.1 Planar Configuration of Semiconductor Memory Device

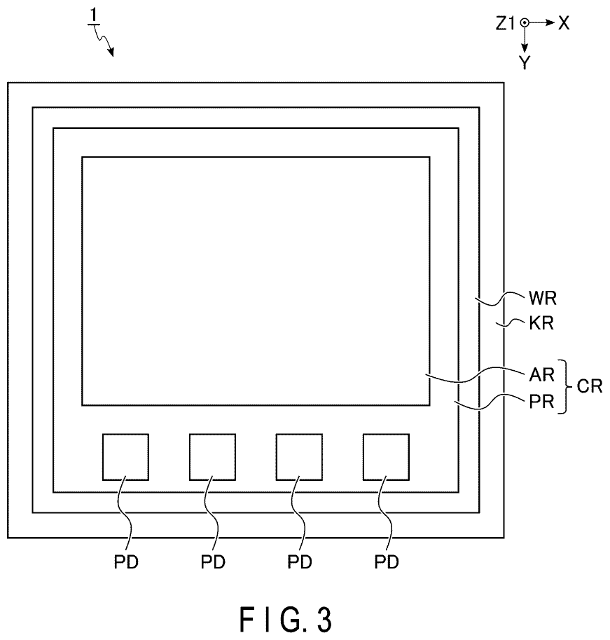

An exemplary planar configuration of the semiconductor memory device 1 will be described with reference to FIG. 3. FIG. 3 is a plan view showing an exemplary planar layout of the semiconductor memory device 1 according to the embodiment.

The semiconductor memory device 1 in the planar layout shown in FIG. 3 is divided into a circuit region PR, a wall region WR, and a kerf region KR. Here, the circuit region CR is divided into an array region AR and a peripheral region PR.

The circuit region CR is provided with elements or components constituting the semiconductor memory device 1 which include, for example, the memory cell array 10, the command register 11, the address register 12, the sequencer 13, the driver module 14, the row decoder module 15, and the sense amplifier module 16. The memory cell array 10 is arranged in the array region AR in the circuit region CR. One or more electrode pads PD are further provided in the peripheral region PR. In one example, each electrode pad PD is exposed at the surface of the semiconductor memory device 1 and functions as a connection pad for coupling with a device, etc., external to the semiconductor memory device 1. In one example, the circuit region CR is a quadrilateral region.

The wall region WR in one example surrounds the outer periphery of the circuit region CR. The wall region WR includes, for example, one or more sealing portions (not shown in the figure) surrounding the outer periphery of the circuit region CR as viewed from above. The sealing portions function as, for example, a crack stopper, an edge seal, etc.

In one example, the kerf region KR surrounds the outer periphery of the wall region WR. The kerf region KR is located in the outermost periphery of the semiconductor memory device 1. The kerf region KR includes, for example, one or more alignment marks for use in the manufacture of the semiconductor memory device 1, a circuit or the like for the performance test of the semiconductor memory device 1, and so on.

### 1.1.4.2 Structure of Memory Cell Array

First, an exemplary structure of the memory cell array 10 arranged in the array region AR in the circuit region CR will be described.

### 1.1.4.2.1 Overall Configuration of Memory Cell Array

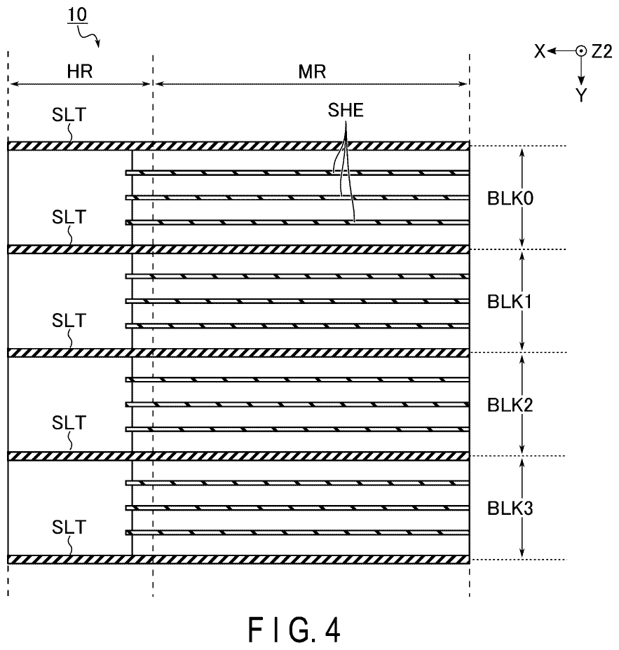

An overall configuration of the memory cell array 10 will be described with reference to FIG. 4. FIG. 4 is a plan view showing an exemplary planar layout of the memory cell array 10 in the semiconductor memory device 1 according to the embodiment. FIG. 4 covers a part corresponding to four blocks BLK0 to BLK3.

The memory cell array 10 includes a stacked interconnect structure and multiple members SLT and SHE. The stacked interconnect structure includes the select gate lines SGD and SGS and the multiple word lines WL. The stacked interconnect structure is a structural component in which layers are stacked in the Z direction according to the staking number of the select gate lines SGD and SGS and the multiple word lines WL. In the following description, the select gate lines SGD and SGS and the multiple word lines WL may also be collectively called “stacked interconnects”.

In one example, the stacked interconnect structure is disposed over a memory region MR and a hookup region HR in the X direction.

The memory region MR refers to a region where data storage substantially takes place.

The hookup region HR refers to a region used for coupling between the stacked interconnects and the peripheral circuit PERI including the row decoder module 15, etc.

The members SLT each extend in the X direction. Each member SLT traverses the stacked interconnect structure throughout the memory region MR and the hookup region HR in the X direction. In one example, each member SLT has a structure filled with an insulator and a plate conductor. Each member SLT is provided so that the stacked interconnects are split into portions next to each other via this member SLT. Each region delimited by the multiple members SLT corresponds to one block BLK. In the following description, an end portion of the blocks BLK0 to BLK3 that is on the block BLK0 side in the Y direction may be called “one Y-direction end”. Also, an end portion of the blocks BLK0 to BLK3 that is on the block BLK3 side in the Y direction may be called “the other Y-direction end”.

The members SHE each extend in the X direction. The embodiment assumes the form where there are three members SHE arranged in every interval between the members SLT next to each other. Each member SHE traverses the stacked interconnect structure throughout the memory region MR in the X direction. In one example, each member SHE has an insulator-filled structure. In one example, each member SHE is provided so that the select gate lines SGD separate from each other and next to each other via this member SHE are formed. Each region delimited by applicable ones of the members SLT and SHE corresponds to one string unit SU.

In one example, the memory cell array 10 repeats the planar layout shown in FIG. 4 in the Y direction.

Note that the memory cell array 10 is not limited to the planar layout described above. For example, the number of members SHE arranged between the neighboring members SLT may be discretionarily set according to the number of string units SU.

### 1.1.4.2.2 Structure of Memory Cell Array in Memory Region

A structure of the memory cell array 10 in the memory region MR will be described.

### 1.1.4.2.2.1 Planar Structure

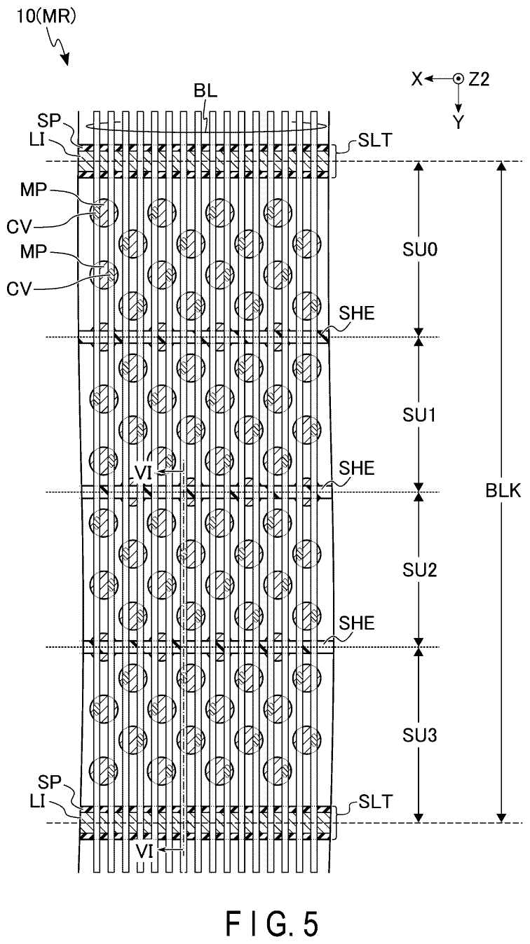

A planar structure of the memory cell array 10 in the memory region MR will be described with reference to FIG. 5. FIG. 5 is a plan view showing an exemplary planar layout of the memory cell array 10 in the semiconductor memory device 1 according to the embodiment.

In the memory region MR, the memory cell array 10 includes multiple memory pillars MP, multiple contacts CV, and multiple bit lines BL. Each member SLT includes a core portion LI and spacers SP.

The memory pillars MP each function as, for example, an individual NAND string NS. In one example, these multiple memory pillars MP are arranged in a pattern of nineteen staggered rows in a region between two neighboring members SLT. Here, in one example, the memory pillars MP in the fifth row, the tenth row, and the fifteenth row from the one Y-direction end each overlap one respective member SHE.

The multiple bit lines BL each extend in the Y direction. Also, the multiple bit lines BL are arranged in the X direction. Each bit line BL overlaps at least one memory pillar MP for each string unit SU. In the example shown in FIG. 5, each bit line BL overlaps two memory pillars MP for each string unit SU. Of the multiple bit lines BL overlapping the same memory pillar MP, one of the bit lines BL is electrically connected to this memory pillar MP via a contact CV. In one example, there is no contact CV between each memory pillar MP that overlaps the member SHE and the bit lines BL. In other words, the memory pillars MP that overlap the member SHE are not electrically connected to the bit lines BL.

The core portion LI is a conductor extending in the X direction. The spacers SP are insulators each provided on the respective side surface of the core portion LI. The core portion L1 is sandwiched between the spacers SP. The core portion LI and the stacked interconnects located next to the core portion LI in the Y direction are electrically separated from each other by the corresponding spacer SP. As such, the core portion LI and the stacked interconnects next to the core portion LI in the Y direction are electrically insulated from each other.

### 1.1.4.2.2.2 Sectional Structure

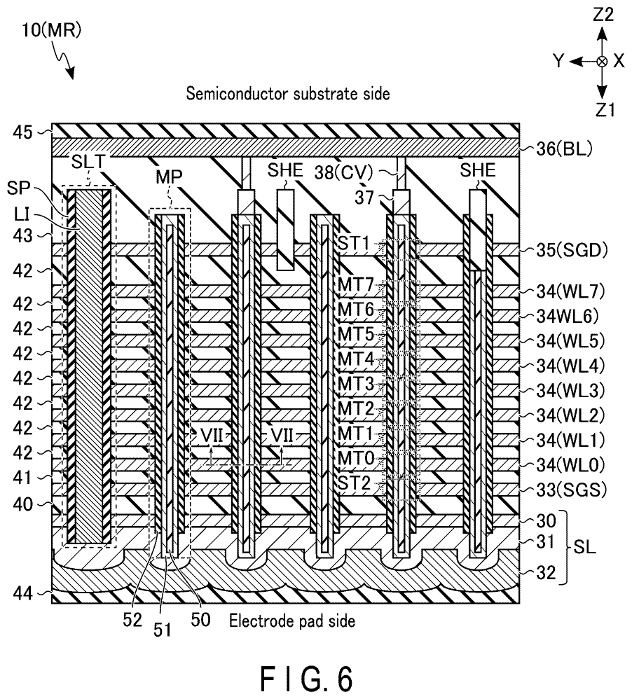

A sectional structure of the memory cell array 10 in the memory region MR will be described with reference to FIG. 6. FIG. 6 is a sectional view taken along the line VI-VI indicated in FIG. 5 and shows an exemplary sectional structure of the memory cell array 10 in the semiconductor memory device 1 according to the embodiment.

The memory cell array 10 here includes conductor layers 30, 31, 32, 33, and 35, conductor layers 34, 36, 37, and 38 with multiple of each provided, insulator layers 40, 41, 43, 44, and 45, and multiple insulator layers 42. FIG. 6 shows five memory pillars MP among the multiple memory pillars MP. Also, FIG. 6 assumes a form where eight conductor layers 34 and eight insulator layers 42 are included as the multiple conductor layers 34 and the multiple insulator layers 42. The memory cell array 10 is provided between the electrode pad PD and the semiconductor substrate of the semiconductor memory device 1 in the Z direction.

In one example, the conductor layer 30 has a plate shape extending over the X-Y plane. The conductor layer 30 is made of a conductive material. The conductive material may be, for example, an impurity-added N-type semiconductor.

The conductor layer 31 is provided on the first surface of the conductor layer 30. The conductor layer 31 is made of a conductive material. This conductive material may be, for example, a doped polysilicon to which an N-type impurity has been added. The conductor layer 31 is, as will be explained later, formed on the first surfaces of the conductor layer 30 and the multiple memory pillars MP. Accordingly, the first surface of the conductor layer 31 in one example has a dent and rise profile corresponding to the multiple memory pillars MP. That is, the conductor layer 31 may have a non-flat first surface.

The conductor layer 32 is provided on the first surface of the conductor layer 31. The conductor layer 32 is made of a conductive material. This conductive material contains, for example, at least one of tungsten, aluminum, titanium, and/or titanium nitride. As will be explained later, the conductor layer 32 is formed on the first surface of the conductor layer 31. Accordingly, the first surface of the conductor layer 32 in one example has a dent and rise profile corresponding to the multiple memory pillars MP, similar to the profile of the first surface of the conductor layer 31. Thus, the conductor layer 32 may have a non-flat first surface as in the case of the conductor layer 31.

The conductor layers 30, 31, and 32 provided as described above function as the source line SL.

The insulator layer 40 is stacked on the second surface of the conductor layer 30. The conductor layer 33 is stacked on the second surface of the insulator layer 40. In one example, the conductor layer 33 has a plate shape extending over the X-Y plane. The conductor layer 33 is used as the select gate line SGS. The conductor layer 33 contains, for example, tungsten.

The insulator layer 41 is stacked on the second surface of the conductor layer 33. On the second surface of the insulator layer 41, the eight conductor layers 34 and the eight insulator layers 42 are stacked toward the Z2 direction in the order of the conductor layer 34, the insulator layer 42, . . . , the conductor layer 34, and the insulator layer 42. In one example, the conductor layers 34 each have a plate shape extending over the X-Y plane. The eight conductor layers 34, one by one toward the Z2 direction, are used as the respective word lines WL0 to WL7. The conductor layers 34 each contain, for example, tungsten.

The conductor layer 35 is stacked on the second surface of the insulator layer 42 that is on the farthest other Z-direction side among the eight insulator layers 42. In one example, the conductor layer 35 has a plate shape extending over the X-Y plane. The conductor layer 35 is used as the select gate line SGD. The conductor layer 35 contains, for example, tungsten. In one example, the conductor layer 35 is electrically insulated for each string unit SU by the multiple members SHE.

The insulator layer 43 is stacked on the second surface of the conductor layer 35. The multiple conductor layers 36 are stacked on the second surface of the insulator layer 43. The conductor layers 36 each extend in the Y direction. FIG. 6 shows one of the multiple conductor layers 36. The conductor layers 36 function as the respective bit lines BL. The multiple conductor layers 36 are electrically connected to the multiple memory pillars MP via the multiple conductor layers 37 and 38.

The stacked structure including the conductor layers 30 to 33 and 35, the conductor layers 34 and 36 to 38 with multiple of each provided, the insulator layers 40, 41, and 43, and the multiple insulator layers 42 as described above is provided in such an arrangement that it is covered by insulators. FIG. 6 shows the insulator layer 44 which contacts the first surface of the conductor layer 32, and the insulator layer 45 which contacts the second surface of the conductor layer 36. Note that, although not illustrated in FIG. 6, the conductor layer 32 is, as will be described later, electrically connected to the peripheral circuit PERI via a conductor layer which is provided on the one side from the conductor layer 32. In one example, also, although not illustrated in FIG. 6, the multiple conductor layers 36 are, as will be described later, electrically connected to the peripheral circuit PERI via a conductor layer which is provided on the other side from the conductor layers 36.

The multiple memory pillars MP extending in the Z direction are provided on the one side from the multiple conductor layers 36. These memory pillars MP penetrate through the conductor layers 30, 33, and 35, and the multiple conductor layers 34.

In one example, the memory pillars MP each include a core member 50, a semiconductor film 51, and a stacked film 52. The core member 50 extends in the Z direction. The semiconductor film 51 surrounds the core member 50. The semiconductor film 51 contacts the conductor layer 31. The stacked film 52 covers the side surface of the semiconductor film 51 except a portion where the semiconductor film 51 and the conductor layer 31 are in contact with each other. The core member 50 contains, for example, an insulator such as silicon oxide. The semiconductor film 51 contains, for example, silicon. The configuration of the stacked film 52 will be described later.

The conductor layers 37 are each provided on the second surface of the corresponding semiconductor film 51. In one example, each conductor layer 37 functions as a columnar contact. The conductor layers 38 are each provided on the second surface of the corresponding conductor layer 37. In one example, each conductor layer 38 functions as the contact CV. With the configuration described above, the conductor layers 37 and 38 couple the applicable semiconductor film 51 and conductor layer 36 together. One conductor layer 36 is coupled with one conductor layer 37 and with one conductor layer 38 for each of the regions delimited by the members SLT and SHE.

In one example, each member SLT splits a set of the conductor layers 30, 33, and 35 and the multiple conductor layers 34. The core portion LI in the member SLT is provided along the member SLT. The second surface of the core portion LI is located between the conductor layer 35 and the conductor layers 36. In one example, the first surface of the core portion LI is located between the conductor layer 30 and the insulator layer 44. The spacers SP are each provided between the core portion LI and a set of the conductor layers 30, 31, 33, and 35 and the multiple conductor layers 34. By the presence of the spacers SP, the core portion LI is separated and electrically insulated from the conductor layers 33 and 35 and the multiple conductor layers 34. Note that, while not illustrated in FIG. 6, the core portion LI may include a barrier metal. More specifically, and for example, the core portion LI may have a structure constituted by a conductive member which contains metal such as tungsten and of which first surface and side surface are covered by the barrier metal. Also, the core portion LI may instead be formed of a semiconductor member, or the member SLT may in its entirety have a structure filled with the same insulator as that of the spacers SP.

A portion where each of the multiple memory pillars MP intersects the conductor layer 33 functions as the respective select transistor ST2. Portions where each of the multiple memory pillars MP intersects the multiple conductor layers 34 function as the memory cell transistors MT, respectively. A portion where each of the multiple memory pillars MP intersects the conductor layer 35 functions as the respective select transistor ST1.

### 1.1.4.2.2.3 Sectional Structure of Memory Pillars

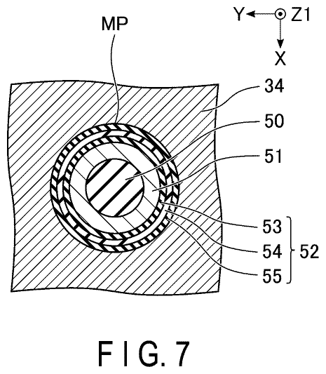

A structure of the memory pillars MP will be described with reference to FIG. 7. FIG. 7 is a sectional view taken along the line VII-VII indicated in FIG. 6 and shows an exemplary sectional structure of the memory pillar MP in the semiconductor memory device 1 according to the embodiment.

The stacked film 52 includes a tunnel insulating film 53, a charge accumulating film 54, and a block insulating film 55. The tunnel insulating film 53 covers the side surface of the semiconductor film 51 except a portion where the semiconductor film 51 and the conductor layer 31 are in contact with each other. The charge accumulating film 54 covers the side surface of the tunnel insulating film 53. The block insulating film 55 covers the side surface of the charge accumulating film 54.

The tunnel insulating film 53 and the block insulating film 55 both contain, for example, silicon oxide. The charge accumulating film 54 contains, for example, silicon nitride. The charge accumulating film 54 is adapted to accumulate electric charges.

In the configuration as above, the semiconductor film 51 functions as a channel of each of the memory cell transistors MT0 to MT7 and the select transistors ST1 and ST2. Also, the charge accumulating film 54 has a function of holding an amount of electric charge corresponding to the data stored in the corresponding memory cell transistor MT. The semiconductor memory device 1 places each of the memory cell transistors MT0 to MT7 and the select transistors ST1 and ST2 into an ON state so as to cause a current to flow between the source line SL and the respective bit line BL through the memory pillar MP and the conductor layers 37 and 38.

### 1.1.4.3 Overall Sectional Structure of Semiconductor Memory Device

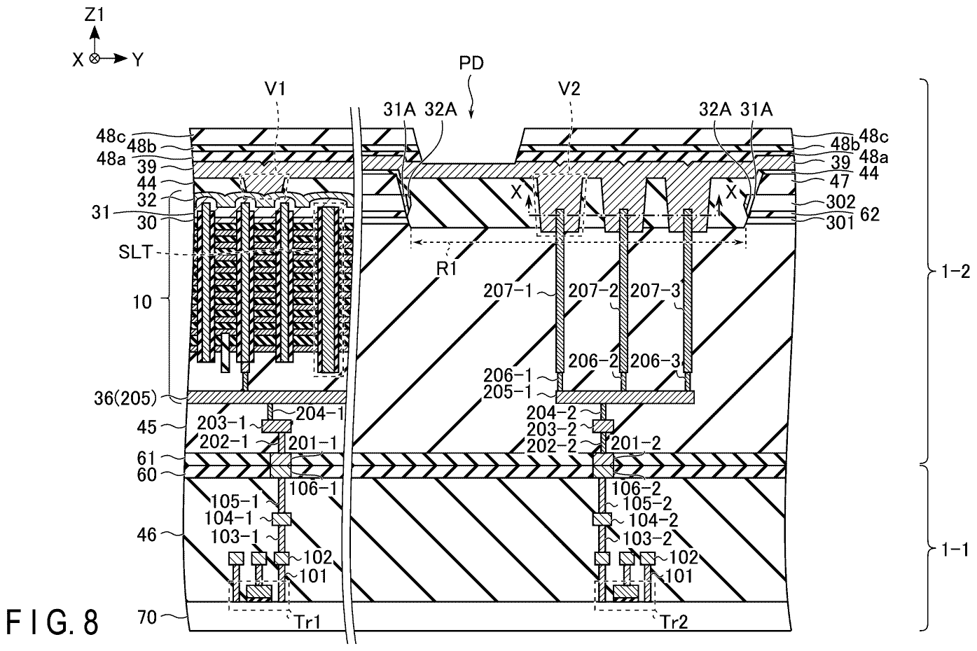

An overall sectional structure of the semiconductor memory device 1 will be described with reference to FIG. 8. FIG. 8 is a sectional view showing an exemplary sectional structure of the circuit region in the semiconductor memory device 1 according to the embodiment. What is shown in FIG. 8 is a sectional structure of a portion of the semiconductor memory device 1.

The semiconductor memory device 1 has a structure including a circuit chip 1-1 and a memory chip 1-2 bonded together.

### 1.1.4.3.1 Circuit Chip

A sectional structure of the circuit chip 1-1 will be described first.

In one example, the circuit chip 1-1 includes a semiconductor substrate 70, multiple conductor layers 101, 102, 103, 104, 105, and 106 forming a portion of the peripheral circuit PERI, and insulator layers 46 and 60. The semiconductor substrate 70 is constituted by, for example, an impurity-added P-type semiconductor.

In one example, the multiple conductor layers 101 to 106 each function as a columnar contact or an interconnect. The multiple conductor layers 103 include conductor layers 103-1 and 103-2. The multiple conductor layers 104 include conductor layers 104-1 and 104-2. The multiple conductor layers 105 include conductor layers 105-1 and 105-2. The multiple conductor layers 106 include conductor layers 106-1 and 106-2.

The insulator layer 46 is provided on the first surface of the semiconductor substrate 70. The insulator layer 46 contains, for example, silicon oxide. The multiple conductor layers 101, 102, 103, 104, and 105 are formed within the insulator layer 46.

The peripheral circuit PERI is provided on the first surface of the semiconductor substrate 70 in the circuit region CR. FIG. 8 shows transistors Tr1 and Tr2 as exemplary components included in the peripheral circuit PERI. In the following description, each of the transistors Tr1 and Tr2 may be simply called a “transistor Tr” if the context does not require discriminating the transistors Tr1 and Tr2 from one another. Each transistor Tr includes a gate insulating film, a gate electrode, and a source and a drain (not shown in the figure) formed in the semiconductor substrate 70.

The multiple conductor layers 101 are provided on the first surfaces of the gate electrode, the source, and the drain of the transistor Tr1, as well as on the first surfaces of the gate electrode, the source, and the drain of the transistor Tr2, respectively. The multiple conductor layers 102 are coupled to the first surfaces of the multiple conductor layers 101, respectively.

The multiple conductor layers 103 are each coupled to the first surface of the applicable one of the multiple conductor layers 102. The conductor layers 103-1 and 103-2 are electrically connected to the respective transistors Tr1 and Tr2.

The conductor layers 104-1 and 104-2 are coupled to the first surfaces of the conductor layers 103-1 and 103-2, respectively.

The conductor layers 105-1 and 105-2 are coupled to the first surfaces of the conductor layers 104-1 and 104-2, respectively. The multiple conductor layers 105 are provided so that their respective first surfaces are flush with the first surface of the insulator layer 46.

The insulator layer 60 is provided on the first surfaces of the insulator layer 46 and the multiple conductor layers 105. The insulator layer 60 contains, for example, silicon oxide.

The multiple conductor layers 106 are provided at the same layer level as the insulator layer 60. The conductor layers 106-1 and 106-2 are coupled to the first surfaces of the conductor layers 105-1 and 105-2, respectively. The multiple conductor layers 106 are provided so that their respective first surfaces are flush with the first surface of the insulator layer 60. The multiple conductor layers 106 each contain, for example, copper. The multiple conductor layers 106 function as multiple connection pads for making electrical connection between the circuit chip 1-1 and the memory chip 1-2. The connection pads may also be called “bonding pads”.

### 1.1.4.3.2 Memory Chip

Referring to the same FIG. 8, a sectional structure of the memory chip 1-2 will be described.

The memory chip 1-2 includes, in one example, multiple conductor layers 201, 202, 203, 204, 205, 206, and 207, a conductor layer 39, insulator layers 44, 45, 47, 48a, 48b, 48c, 61, and 62, semiconductor layers 301 and 302, and the memory cell array 10.

In one example, the multiple conductor layers 201 to 207 each function as a columnar contact or an interconnect. The multiple conductor layers 201 include conductor layers 201-1 and 201-2. The multiple conductor layers 202 include conductor layers 202-1 and 202-2. The multiple conductor layers 203 include conductor layers 203-1 and 203-2. The multiple conductor layers 204 include conductor layers 204-1 and 204-2. The multiple conductor layers 205 include conductor layers 36(205) and 205-1. The multiple conductor layers 206 include conductor layers 206-1, 206-2, and 206-3. The multiple conductor layers 207 include conductor layers 207-1, 207-2, and 207-3.

The insulator layer 61 in the memory chip 1-2 is provided on the first surface of the circuit chip 1-1. The insulator layer 61 contains, for example, silicon oxide.

The multiple conductor layers 201 are provided at the same layer level as the insulator layer 61. The conductor layers 201-1 and 201-2 are coupled to the first surfaces of the conductor layers 106-1 and 106-2, respectively. The multiple conductor layers 201 are provided so that their respective second surfaces are flush with the second surface of the insulator layer 61. The multiple conductor layers 201 each contain, for example, copper. The multiple conductor layers 201 function as multiple connection pads for making electrical connection between the circuit chip 1-1 and the memory chip 1-2. With the configuration described above, the circuit chip 1-1 and the memory chip 1-2 are electrically connected to each other via the multiple conductor layers 106 and 201.

The insulator layer 45 is provided on the first surfaces of the insulator layer 61 and the multiple conductor layers 201. The multiple conductor layers 202 to 206, portions of the multiple conductor layers 207, and a portion of the memory cell array 10 are formed within the insulator layer 45.

The memory cell array 10 is formed in such an arrangement that the conductor layer 32 is located on the one Z-direction side and the conductor layer 36(205) is located on the other Z-direction side.

The conductor layer 202-1 is provided on the first surface of the conductor layer 201-1. The conductor layer 203-1 is coupled to the first surface of the conductor layer 202-1. The conductor layer 204-1 is coupled to the first surface of the conductor layer 203-1. The conductor layer 204-1, through its first surface, is coupled to the conductor layer 36(205). With the above configuration, the conductor layer 36 and the transistor Tr1 are made capable of being coupled to each other. In other words, the bit line BL of the memory cell array 10 and the peripheral circuit PERI are electrically connected to each other.

The conductor layer 202-2 is provided on the first surface of the conductor layer 201-2. The conductor layer 203-2 is provided on the first surface of the conductor layer 202-2. The conductor layer 204-2 is provided on the first surface of the conductor layer 203-2. The conductor layer 205-1 is provided on the first surface of the conductor layer 204-2. The conductor layers 206-1, 206-2, and 206-3 are provided on the first surface of the conductor layer 205-1. The conductor layer 207-1 is provided on the first surface of the conductor layer 206-1. The conductor layer 207-1 extends in the Z direction. The conductor layer 207-1 includes, on the one side, a portion projecting from the insulator layer 45. In one example, the conductor layer 207-1 functions as a columnar contact.

The conductor layers 207-2 and 207-3 are provided on the first surfaces of the conductor layers 206-2 and 206-3, respectively, as with the conductor layer 206-1. The conductor layers 207-2 and 207-3, similar to the conductor layer 207-1, extend in the Z direction. Also, the conductor layers 207-2 and 207-3 each include, on the one side, a portion projecting from the insulator layer 45. In one example, the conductor layers 207-2 and 207-3 each function as a columnar contact. The conductor layers 207-1, 207-2, and 207-3 are electrically connected to the same conductor layer 201-2 via the conductor layer 205-1 in the insulator layer 45. Note that the conductor layers 207-1, 207-2, and 207-3 may instead be electrically connected to the conductor layer 201-2 in such a form that the connections are made via the common conductor layer 203-2 and further via multiple conductor layers 204 on the first surface of the conductor layer 203-2 and also multiple conductor layers 205, provided for the respective conductor layers 207-1, 207-2, and 207-3.

In one example, the semiconductor layer (pattern portion) 301 is provided on portions of the first surface of the insulator layer 45 that are other than the region of the memory cell array 10 and that are next to, and sandwich, a region R1 encompassing the positions where the multiple conductor layers 207 are provided. The semiconductor layer 301 and the conductor layer 30 in the memory cell array 10 are at the same layer level as each other. The insulator layer 62 is provided on the first surface of the semiconductor layer 301. The semiconductor layer 302 is provided on the first surface of the insulator layer 62. The semiconductor layers 301 and 302 are, for example, non-doped polysilicon. The semiconductor layers 301 and 302 are electrically insulated from the source line SL. The insulator layer 47 is provided on the first surface of the semiconductor layer 302. Due to the above configuration, the region R1 shown in FIG. 8 is sandwiched in the Y direction by two wall surfaces each constituted by the semiconductor layers 301 and 302 and the insulator layers 47 and 62.

In one example, the first surface of the insulator layer 45 in the region R1 is on the other side from the first surface of the insulator layer 45 in the regions next to the region R1 and other than the region of the memory cell array 10. In other words, the first surface of the insulator layer 45 in the region R1 is, for example, on the other side from the second surface of the semiconductor layer 301.

The insulator layer 44 is provided on the first surfaces of the insulator layer 45 in the region R1 and the insulator layer 47, and also on the first surface of the conductor layer 32. In one example, the first surface of the insulator layer 44 has a level difference near the boundary between the region R1 and the region next to the region R1. More specifically, the first surface of the insulator layer 44 located in the region R1 is on the other side from the first surface of the insulator layer 44 located on the first surface of the insulator layer 47. Also, the first surface of the insulator layer 44 located in the region R1 is at substantially the same level as the first surface of the insulator layer 44 located on the first surface of the conductor layer 32. While not shown in FIG. 8, in one example, the first surface of the insulator layer 44 also has a level difference near the boundary between the region where the conductor layer 32 is provided and its neighboring region.

On the two wall surfaces sandwiching the region R1 in the Y direction and constituted by the semiconductor layers 301 and 302 and the insulator layers 47 and 62, conductor layers 31A and 32A resulting from the later described formation of the conductor layers 31 and 32 may be provided. Note that, in one example, outside the part shown in FIG. 8, the region R1 is also sandwiched in the X direction by a configuration similar to the configuration in the Y direction. That is, in one example, the semiconductor memory device 1 includes two wall surfaces sandwiching the region R1 in the X direction and constituted by the semiconductor layers 301 and 302 and the insulator layers 47 and 62. These two wall surfaces may also be provided with the conductor layers 31A and 32A resulting from the later described formation of the conductor layers 31 and 32. Thus, as described above, the region R1 in one example is surrounded by four wall surfaces in top view. With the above configuration, the conductor layers 31A and 32A may be provided between each of the wall surfaces and the insulator layer 44. The conductor layers 31A and 32A may be provided partially or entirely over each wall surface.

The first surface of the conductor layer 32 includes a portion where the insulator layer 44 is not provided. Also, the respective one-side portions of the multiple conductor layers 207 that project from the insulator layer 45, and portions of the first surface of the insulator layer 45 that respectively surround the multiple conductor layers 207 are not covered by the insulator layer 44. The conductor layer 39 is provided on the first surface of the insulator layer 44, the portion of the first surface of the conductor layer 32 where the insulator layer 44 is not provided, the one-side portions of the multiple conductor layers 207 that project from the insulator layer 45, and the portions of the first surface of the insulator layer 45 that respectively surround the multiple conductor layers 207. Due to this configuration, the conductor layer 39 includes a coupling portion V1 in contact with the conductor layer 32, multiple coupling portions V2 in contact with the multiple conductor layers 207, and an extension constituting a portion other than the coupling portions V1 and V2 and extending in the Y direction. The conductor layer 39 functions as an interconnect layer (an interconnect). The conductor layer 39 contains, for example, aluminum. Here, in one example, the first surface and the second surface of the extension of the conductor layer 39 each have a level difference resulting from the level difference in the first surface of the insulator layer 44. Due to the configuration above, the extension of the conductor layer 39 includes, in top view, a first sub-portion overlapping the semiconductor layer 301 and a second sub-portion overlapping an insulator portion of the insulator layer 44 that is located between a set of the coupling portions V2 and the semiconductor layer 301. The second surface of the first sub-portion is on the one side from the second surface of the second sub-portion.

The coupling portion V1 may be regarded as a via that fills a space assumed between the extension of the conductor layer 39 and the conductor layer 32. The multiple coupling portions V2 may each be regarded as a via that fills a space assumed between the extension of the conductor layer 39 and both of the conductor layer 207 corresponding to the respective coupling portion V2 and the portion of the first surface of the insulator layer 45 that surrounds this conductor layer 207. The multiple coupling portions V2 are formed to embrace the respective one-side portions of the conductor layers 207 that project from the insulator layer 45. The structures of the coupling portions V1 and V2 will be described in more detail later. The extension of the conductor layer 39 is provided on the one side from the first surface of the conductor layer 32. That is, the extension of the conductor layer 39 is provided on the one side from the farthest one-side first surface of the source line SL. Also, the extension of the conductor layer 39 is provided on the one side from the first surface of the semiconductor layer 302.

With the above configuration, for example, the conductor layer 32 and the transistor Tr2 can be coupled to each other via the conductor layers 39, 101 to 106, and 201 to 207. That is, the source line SL and the peripheral circuit PERI are electrically connected to each other.

Note that the semiconductor memory device 1 may include, in the cross-section not shown in the figure, a configuration (an interconnect) that is electrically insulated from the portion (an interconnect) of the conductor layer 39 including the coupling portion V1 and that is similar to the electrode pad PD with the portion of the conductor layer 39 including the multiple coupling portions V2. Such a configuration is, for example, electrically connected to the peripheral circuit PERI via the conductor layers 101 to 106 and 201 to 207.

The extension of the conductor layer 39 includes a region exposed at the first surface of the semiconductor memory device 1. In one example, this region forms the electrode pad PD for coupling with a device external to the semiconductor memory device 1. The electrode pad PD is provided at a position overlapping the region R1 in the Z direction. As such, the semiconductor layers 301 and 302 are not present in the region overlapping the electrode pad PD in the Z direction. Also, in one example, the position where the electrode pad PD is provided does not overlap the multiple coupling portions V2 in the Z direction. Due to the above configuration, in the region overlapping the electrode pad PD in the Z direction, the insulator layer 44 is provided at the same layer level as the semiconductor layers 301 and 302 and the insulator layer 62.

On the first surface of the conductor layer 39 except a portion where the electrode pad PD is provided, the insulator layers 48a, 48b, and 48c are stacked in this order in the Z direction. The insulator layer 48a in one example is an insulator containing silicon oxide, etc. The insulator layers 48b and 48c in one example contain silicon nitride, a resin material, etc. The insulator layers 48b and 48c in one example function as a passivation film.

### 1.1.4.3.3 Structure Around Coupling Portions

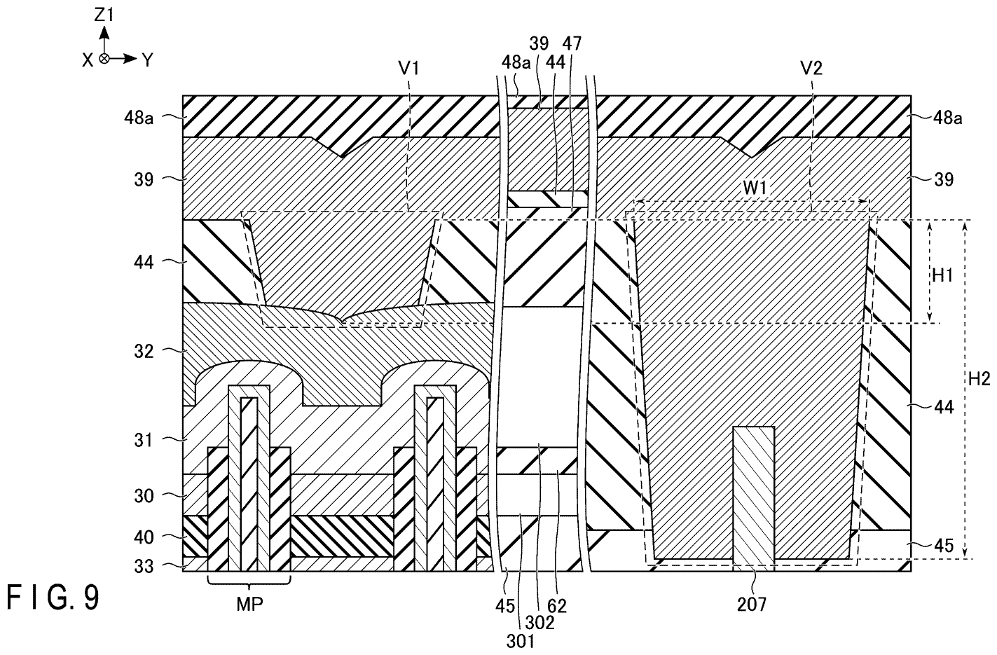

A structure around the coupling portions V1 and V2 will be described with reference to FIG. 9. FIG. 9 is a sectional view showing examples of the coupling portion between the interconnect layer and the source line and that between the interconnect layer and the contact in the semiconductor memory device 1 according to the embodiment. FIG. 9 shows a part including the coupling portion V1, a part including one of the coupling portions V2, and a part including the insulator layers 47 and 62 next to the region R1.

The second surface of the coupling portion V2 is, for example, on the other side from the first surface of the conductor layer 32. That is, the second surface of the coupling portion V2 in one example is on the other side from the farthest one-side first surface of the source line SL. Also, the second surface of the coupling portion V2 is, for example, on the other side from the first surface of the conductor layer 30 and the first surface of the semiconductor layer 301.

Here, the second surface of the extension of the conductor layer 39 in the memory region MR except for the coupling portion V1 and the second surface of the extension of the conductor layer 39 in the region R1 except for the coupling portion V2 are at substantially the same level in the Z direction. As such, the one-side end of the coupling portion V1 and the one-side end of the coupling portion V2 are aligned at this level. Accordingly, the coupling portion V2 has a height H2 which is greater than a height H1 of the coupling portion V1. The height H1 is a distance from the second surface of the coupling portion V1 to this level. The height H2 is a distance from the second surface of the coupling portion V2 to this level.

Also, assuming that the width of the coupling portion V2 in the Y direction is W1, the aspect ratio between the height H2 and the width W1, H2/W1, is, in one example, approximately 1.5 or less. Assuming that the width of the coupling portion V2 in the X direction is W2 (not shown in the figure), the aspect ratio between the height H2 and the width W2, H2/W2, is, in one example, also approximately 1.5 or less. With each coupling portion V2 intended to have such a configuration, the process of manufacturing the semiconductor memory device 1, which will be described later, can obviate the occurrence of an event where trenches corresponding to the coupling portions V2 have been insufficiently filled with a conductor in the course of the formation of the conductor layer 39.

Note, additionally, that recesses resulting from the conductor filling the trenches may be present at portions of the first surface of the conductor layer 39 that overlap the respective coupling portions V1 and V2 in the Z direction.

### 1.1.4.3.4 Structure Around Multiple Coupling Portions V2

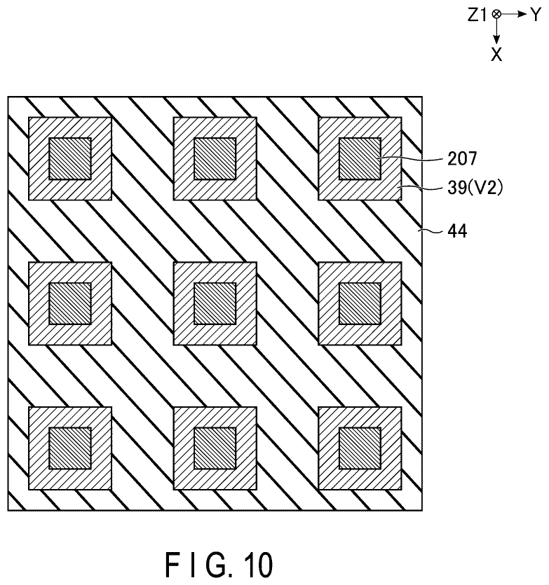

A structure around the multiple coupling portions V2 will be described to a further extent with reference to FIG. 10. FIG. 10 is a sectional view taken along the line X-X indicated in FIG. 8 and shows exemplary coupling portions between the interconnect layer and the respective contacts in the semiconductor memory device 1 according to the embodiment.

In one example, the multiple conductor layers 207 functioning as respective contacts are arranged in a grid pattern in an X-Y cross-section. FIG. 10 shows a form where nine conductor layers 207 are arranged in a 3×3 grid pattern.

In one example, the multiple coupling portions V2 are arranged in a grid pattern in an X-Y cross section so that they correspond to the multiple conductor layers 207, respectively. The multiple coupling portions V2 are each provided to surround, in the X-Y cross section, one of the multiple conductor layers 207 that corresponds to the respective coupling portion V2.

### 1.1.4.3.5 Sectional Structure of Connection Pads

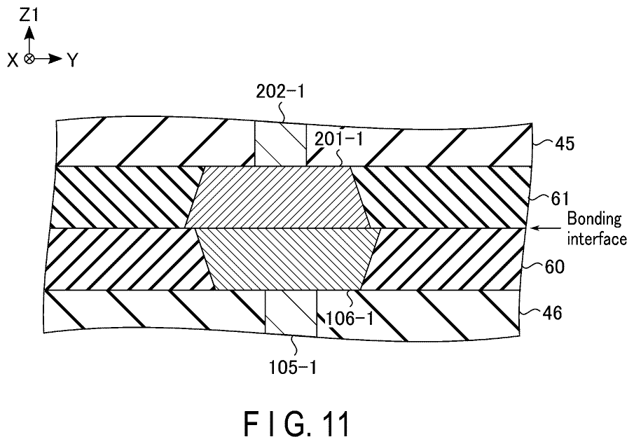

A sectional structure of the connection pads will be described with reference to FIG. 11. FIG. 11 is a sectional view showing an exemplary sectional structure of the connection pads in the semiconductor memory device 1 according to the embodiment. The description will be given of a part where the conductor layer 106-1 and the conductor layer 201-1 are coupled to each other, and such a description is likewise applicable to the parts where the other multiple conductor layers 106 and their respective corresponding conductor layers 201 are coupled to each other.

In one example, the conductor layer 106-1 and the conductor layer 201-1 have comparable areas in the bonding interface where bonding between the circuit chip 1-1 and the memory chip 1-2 takes place. Assuming that the conductor layers 106-1 and 201-1 are both copper, the conductor layers 106-1 and 201-1 would be integrated and make recognition of the boundary between their copper difficult. Nevertheless, the bond state will be recognizable from, for example, deformations in shapes of the bonded conductor layers 106-1 and 201-1 that would occur due to misaligned bonding positions. Also, for example, the bond state will be recognizable from displaced barrier metals for copper. That is, the bond state can be recognized from inclusion of discontinuous portions in the side surface.

Note also that the conductor layers 106-1 and 201-1, if formed through a damascene method, each have tapered side surfaces. Thus, each side wall of the conductor layer 106-1 and each side wall of the conductor layer 201-1 do not together form a straight line. Accordingly, the Z direction cross-section of a portion where the conductor layers 106-1 and 201-1 are bonded to each other shows a non-rectangular profile.

In addition to the above, bonding of the conductor layers 106-1 and 201-1 produces a structure in which barrier metals cover the first, second, and side surfaces of the copper elements forming the conductor layers 106-1 and 201-1. On the other hand, general interconnect layers which employ copper are provided with an insulator layer (silicon nitride, nitrogen-containing silicon carbide, or the like) over the top surface of the copper so as to give an anti-copper-oxidation function, and no barrier metal is provided. Thus, it is possible to distinguish from general interconnect layers even if misalignment in bonding positions is not involved.

### 1.2 Method for Manufacturing Semiconductor Memory Device

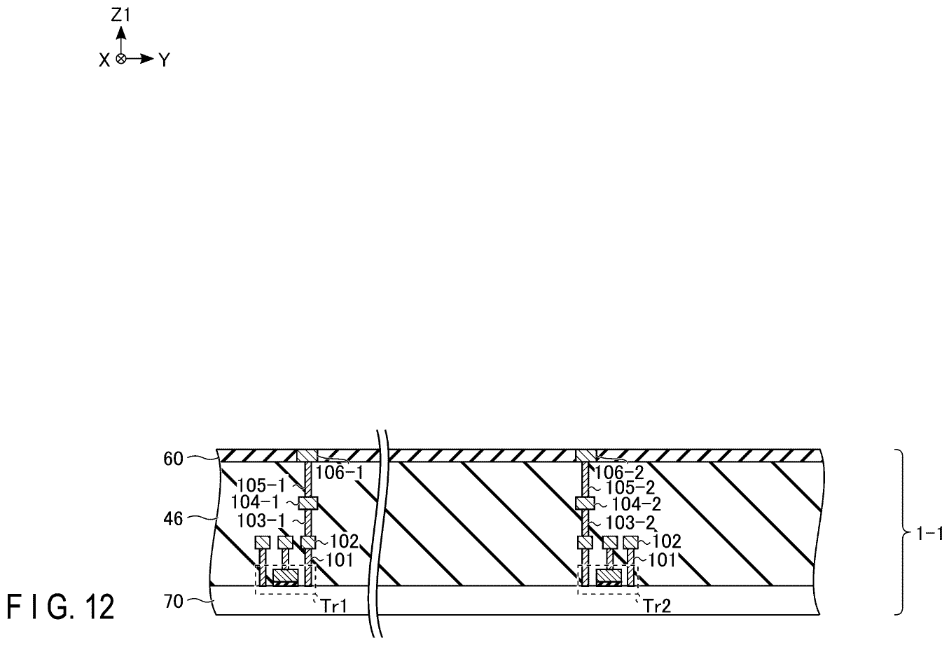

A method for manufacturing the semiconductor memory device 1 will be described with reference to FIGS. 12 to 18. FIGS. 12 to 18 are sectional views for explaining an exemplary method for manufacturing the semiconductor memory device 1 according to the embodiment. The sectional views shown in FIGS. 12 to 18 each show a part corresponding to FIG. 8.

First, as shown in FIG. 12, elements included in the peripheral circuit PERI, such as the transistors Tr1 and Tr2, the multiple conductor layers 101 to 106, and the insulator layers 46 and 60, are formed on the semiconductor substrate 70. In other words, the circuit chip 1-1 is formed.

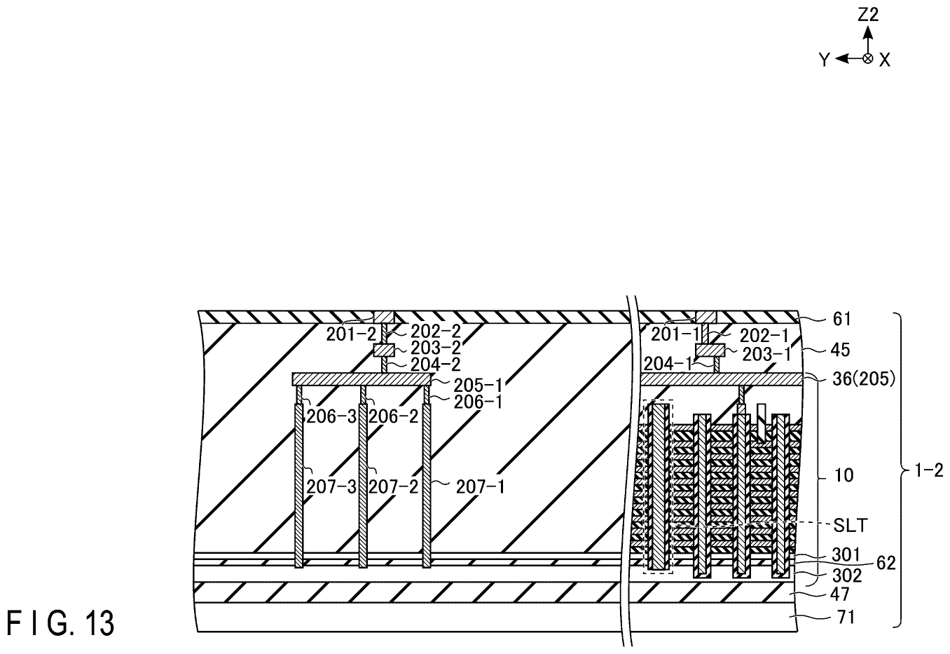

Next, as shown in FIG. 13, the insulator layer 47, the conductor layers 33 and 35, the multiple conductor layers 34 and 201 to 207, the semiconductor layers 301 and 302, the insulator layers 40, 41, 43, and 62, the multiple insulator layers 42, structural portions corresponding to the multiple memory pillars MP, the multiple members SLT and SHE, and the insulator layer 45 portion and the insulator layer 61 which cover these elements are formed on the second surface of a semiconductor substrate 71 formed of an impurity-added P-type semiconductor. In other words, a structure corresponding to the memory chip 1-2 is formed. Here, the semiconductor layers 301 and 302 and the insulator layers 47 and 62 are formed over the entire second surface of the semiconductor substrate 71.

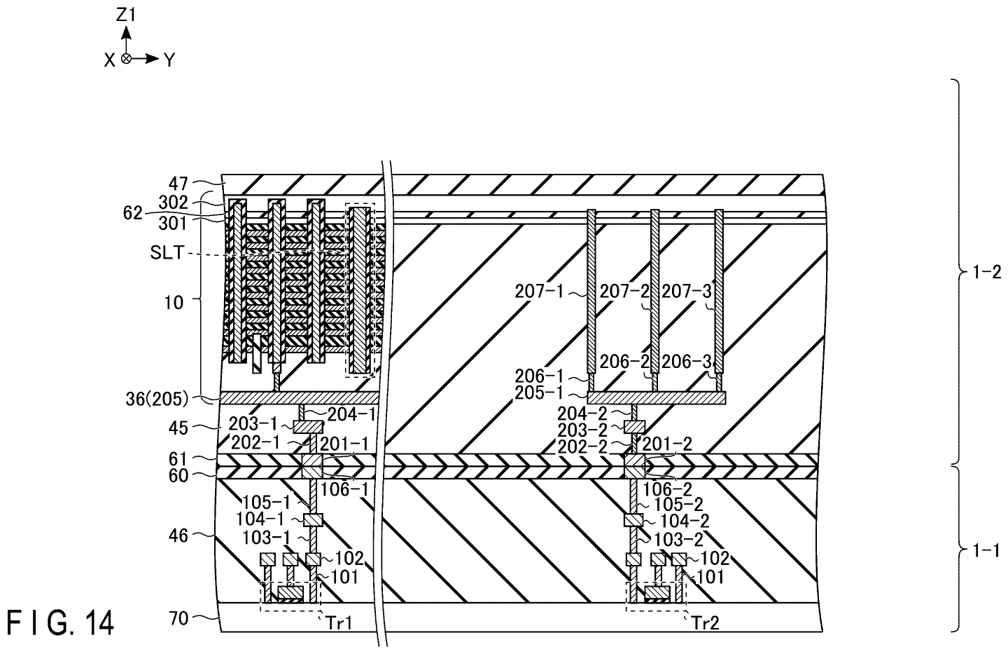

Then, as shown in FIG. 14, the circuit chip 1-1 and the structure corresponding to the memory chip 1-2 are bonded together by a bonding process. More specifically, the circuit chip 1-1 and the structure corresponding to the memory chip 1-2 are put in such an arrangement that the multiple conductor layers 106 functioning as the connection pads of the circuit chip 1-1 and the multiple conductor layers 201 functioning as the connection pads of the memory chip 1-2 face each other. The connection pads facing each other are joined together by a heat treatment. Subsequently, the semiconductor substrate 71 is removed by, for example, chemical mechanical polishing (CMP).

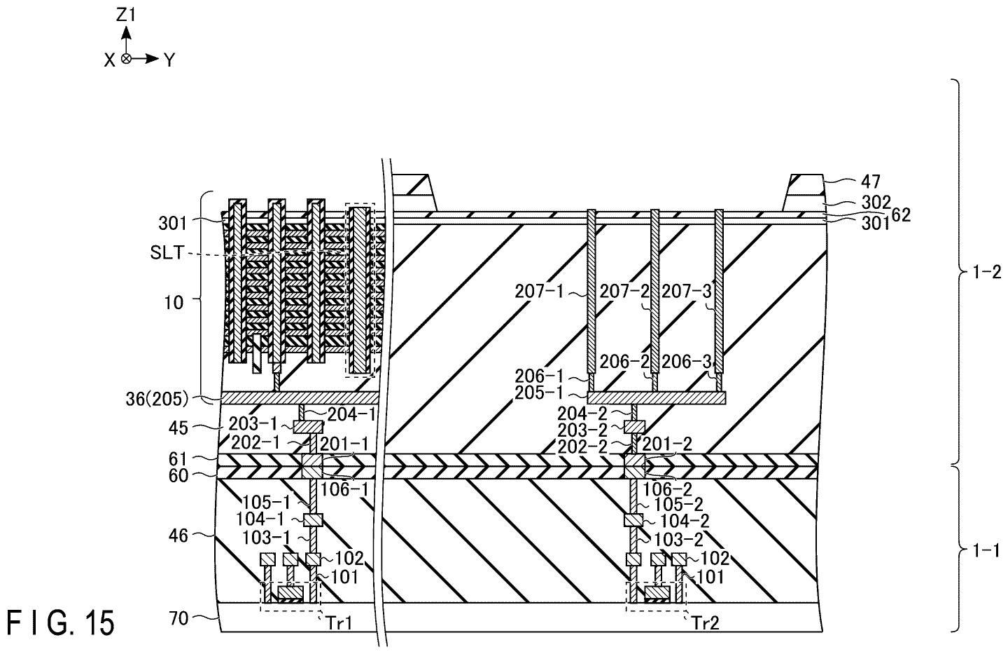

Then, as shown in FIG. 15, the insulator layer 47 and the semiconductor layer 302 in the locations corresponding to the memory cell array 10 and the region R1 are removed. In one example, removal of the portions corresponding to the memory cell array 10 and removal of the portions corresponding to the region R1 are conducted at the same time.

Also, in each memory pillar MP, a portion of the stacked film 52 that is located on the one side from the insulator layer 62 is removed. This exposes the semiconductor film 51 located on the one side from the insulator layer 62, at the surface. Also, the insulator layer 62 in the locations corresponding to the memory cell array 10 and the region R1 is removed. This exposes the semiconductor layer 301 at the portions of the surface that correspond to the memory cell array 10 and the region R1. Here, in the portion corresponding to the memory cell array 10, for example, the respective one-side portions of the multiple members SLT are also exposed at the surface. In the location corresponding to the region R1, for example, the respective one-side portions of the multiple conductor layers 207 are also exposed at the surface.

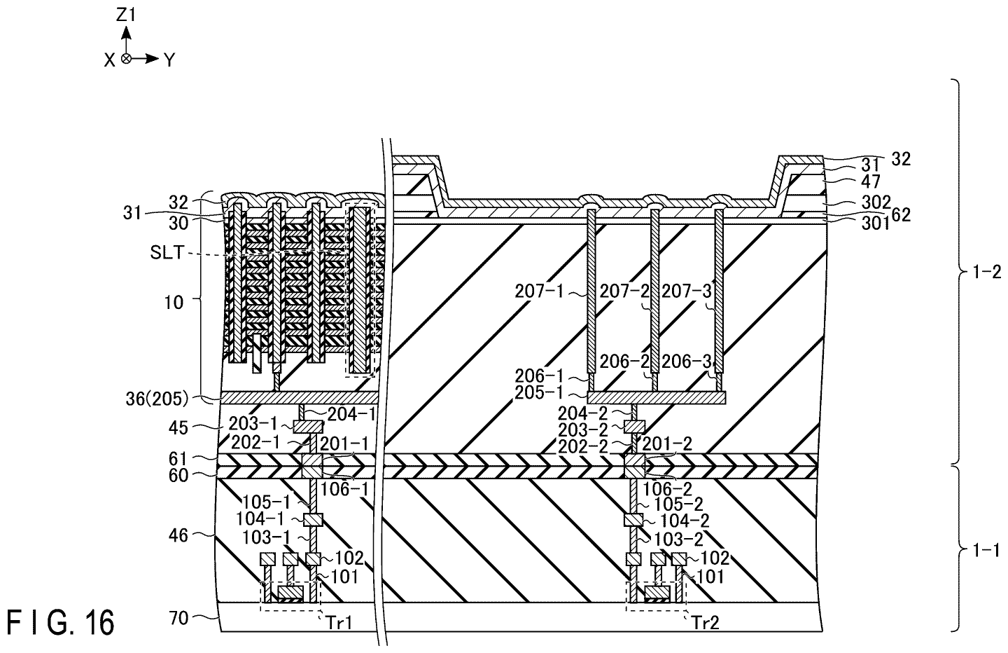

Next, as shown in FIG. 16, the conductor layers 31 and 32 are stacked on the surface-exposed portions of the first surface of the semiconductor layer 301, the surface-exposed portions of the memory pillars MP, the first surface of the insulator layer 47, the one-side portions of the multiple members SLT, and the one-side portions of the multiple conductor layers 207. Here, a portion of the semiconductor layer 301 that corresponds to the memory cell array 10 is turned into the conductor layer 30 by diffusion of impurity. More specifically, this step first includes formation of an amorphous silicon film on the surface-exposed portions of the first surface of the semiconductor layer 301, the surface-exposed portions of the memory pillars MP, the first surface of the insulator layer 47, the one-side portions of the multiple members SLT, and the one-side portions of the multiple conductor layers 207. Then, an impurity is injected into the formed amorphous silicon film, and processes such as a heat treatment are subsequently conducted so that the impurity is caused to diffuse across the semiconductor layer 301 and the formed amorphous silicon film is reformed into polysilicon. The conductor layers 30 and 31 are thus formed. Subsequently, the conductor layer 32 is formed on the first surface of the obtained conductor layer 31.

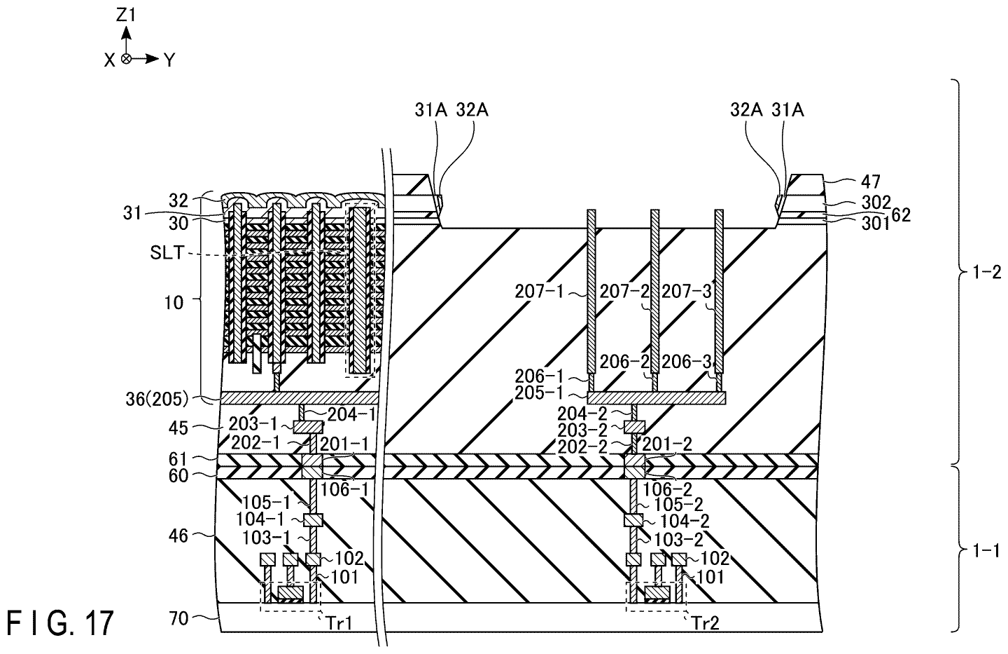

Then, etching or the like is conducted with a mask so that portions of the thus-formed conductor layers 31 and 32 that correspond to regions other than the memory cell array 10 are removed as shown in FIG. 17. Here, in the location corresponding to the region R1, the respective one-side portions of the semiconductor layer 301 and the insulator layer 45 are also removed. Accordingly, in the location corresponding to the region R1, for example, a portion of the first surface of the insulator layer 45 and the respective one-side portions of the multiple conductor layers 207 that project from the insulator layer 45 are exposed at the surface. Also, as a result of the above process, the conductor layers 31A and 32A, which are traces of the conductor layers 31 and 32, are formed on the wall surfaces constituted by the semiconductor layers 301 and 302 and the insulator layers 47 and 62 as shown in FIG. 17.

Subsequently, the insulator layer 44 is formed on the first surface of the conductor layer 32, the first surface of the insulator layer 47, the surface-exposed portion of the first surface of the insulator layer 45 in the location corresponding to the region R1, the one-side portions of the multiple conductor layers 207 that project from the insulator layer 45, and the conductor layers 31A and 32A. The one-side portion of the insulator layer 44 is removed by CMP. Here, the process of CMP is not required to be continued until the first surface of the thus-formed structure is flattened. In this way, it is possible to form a level difference in the first surface of the insulator layer 44 near the boundary between the portion corresponding to the region R1 and its neighboring portion.

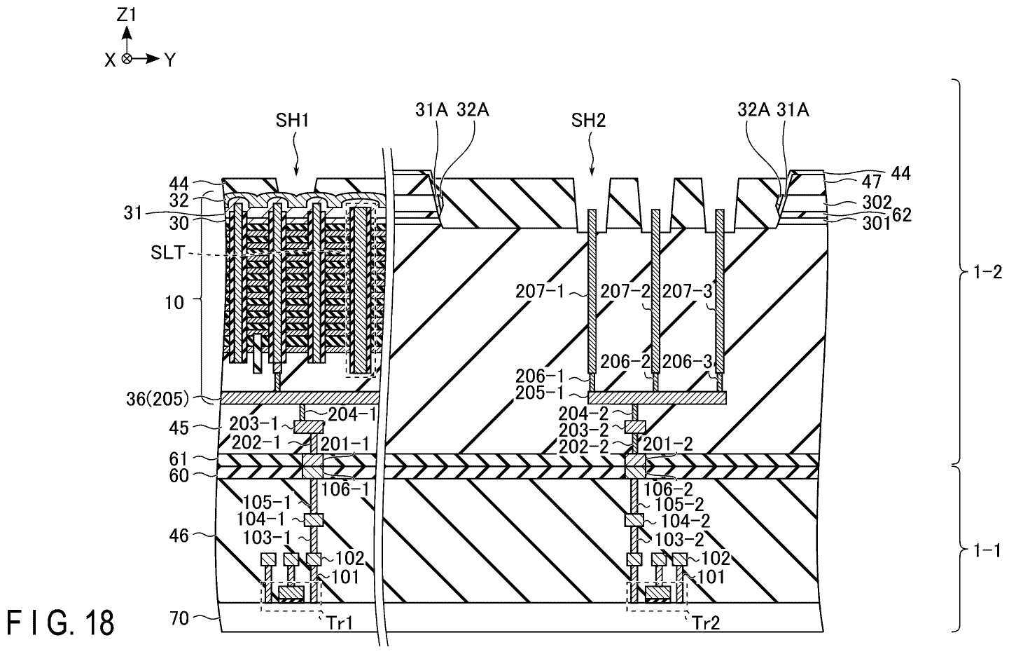

Next, as shown in FIG. 18, a trench SH1 corresponding to the coupling portion V1 and multiple trenches SH2 corresponding to the multiple coupling portions V2 are formed. More specifically, anisotropic etching is conducted using a mask that includes openings corresponding to the coupling portion V1 and the multiple coupling portions V2 so that portions where the coupling portion V1 and the multiple coupling portions V2 will be formed are removed at the same time. The trench SH1 and the multiple trenches SH2 are thus formed. In one example, this anisotropic etching is continued until the insulator layer 45 is exposed at each of the locations overlapping the openings corresponding to the respective coupling portions V2 in the Z direction. Here, portions of the insulator layer 45 at these locations may be removed. Accordingly, after the anisotropic etching, the portions of the first surface of the insulator layer 45 that overlap the respective trenches SH2 in the Z direction are located on the other side from the remaining portions of the first surface of the insulator layer 45. The anisotropic etching in this process is, for example, reactive ion etching (RIE). The mask is then removed. Note that the simultaneous formation of the trench SH1 and the multiple trenches SH2 is possible by the above described etching having a high selectivity between the insulator layers 44 and 45 and the conductor layer 32.

Then, the conductor layer 39 is formed on the first surface of the insulator layer 44, the portion of the first surface of the conductor layer 32 where the insulator layer 44 is not provided, the one-side portions of the multiple conductor layers 207 that project from the insulator layer 45, and the portions of the first surface of the insulator layer 45 that respectively surround the multiple conductor layers 207. Here, the conductor layer 39 is formed so that it fills the trench SH1 and the multiple trenches SH2. The portion of the conductor layer 39 that fills the trench SH1 constitutes the coupling portion V1. The portions of the conductor layer 39 that fill the multiple trenches SH2 constitute the respective coupling portions V2. Further, the insulator layers 48a, 48b, and 48c are formed over the first surface of the thus-formed structure except for a portion of the conductor layer 39 that corresponds to the electrode pad PD.

The semiconductor memory device 1 is formed through the manufacturing process as described above.

Note that the above described manufacturing process is only an example, and it is possible to adopt modifications such as insertion of other processes between the process steps and changes in the order of the steps. For example, the process of forming the circuit chip 1-1 as illustrated in FIG. 12 and the process of forming the structure corresponding to the memory chip 1-2 as illustrated in FIG. 13 may be concurrently performed, as the circuit chip 1-1 and the structure corresponding to the memory chip 1-2 are formed using the respective, mutually different semiconductor substrates 70 and 71.

### 1.3 Effects

According to one or more embodiments, degradation of the current characteristics of the semiconductor memory device 1 can be suppressed. Effects of the embodiments will be described.

In one exemplary embodiment, the semiconductor memory device 1 includes a circuit chip 1-1 including a semiconductor substrate 70 defining an array region AR and a peripheral region PR, and a memory chip 1-2 contacting the circuit chip 1-1 in the Z direction and electrically connected to the circuit chip 1-1 via a connection pad provided at a boundary region with the circuit chip 1-1. The memory chip 1-2 includes a memory cell array 10 provided in the array region AR, a conductor layer 207 provided in the peripheral region PR and functioning as a contact, and a conductor layer 39 functioning as an interconnect. The conductor layer 207 extends in the Z direction and is electrically connected to the connection pad. The conductor layer 39 includes a coupling portion V2 for electrical connection with a one-side portion of the conductor layer 207, and an extension continuously extending in the Y direction from the top end (the one-side end) of the coupling portion V2 and on the one Z-direction side from the first surface of a source line SL. The coupling portion V2 has a shape in which a trench on the one Z-direction side of the conductor layer 207 is filled up to the level of the second surface of the extension. Also, the second surface of the coupling portion V2 is located on the other Z-direction side from the first surface of the source line SL. Such a configuration can, for example, prevent the amount of electric current flowing through the conductor layer 39 where the electrode pad PD is formed, and also the electro-migration (EM) resistance, from decreasing. Therefore, degradation of the current characteristics of the semiconductor memory device 1 can be suppressed.

More specifically, and for example, supposing a comparative example where an interconnect layer coupled with a contact has a staircase structure in the Y-Z cross-section, a portion that extends in the Z direction and forms the level difference in the interconnect layer may only have a small thickness. In such instances, it would be difficult for the interconnect layer to meet the desired current value for the device, or the EM resistance could drop.

According to an exemplary embodiment, the conductor layer 39 located on the one side from the insulator layer 44 is coupled to the multiple conductor layers 207 via the multiple coupling portions V2. Therefore, unlike in the comparative example, the conductor layer 39 according to the embodiment does not include a staircase structure on the other side from its extension extending in the Y direction. In other words, involvement of a thin interconnect layer is avoided. Thus, the semiconductor memory device 1 according to the embodiment can suppress degradation of its current characteristics.

According to an exemplary embodiment, the insulator layer 44 is provided at the same layer level as the conductor layer 30 in the region overlapping the electrode pad PD in the Z direction. As such, the semiconductor layers 301 and 302 are not in this region. With such a structure, a distance in the Z direction between the electrode pad PD and the interconnect layer provided on the other side from the electrode pad PD can be secured. Accordingly, interference between the electrode pad PD and the interconnect layer having a different potential than the electrode pad PD is suppressed. Therefore, the interface speed can be prevented from slowing down.

According to an exemplary embodiment, further, the manufacturing cost can be reduced as compared to the comparative example mentioned above. More specifically, the device according to the comparative example is manufactured through a process in which, for example, a structure including a source line and an insulator layer covering the source line are formed, and then this insulator layer and a polysilicon layer that is included in the same layer level as the source line are removed in a region outside the memory cell array and including contacts in top view. Then, for example, an insulator layer is formed on the surface of the region. Here, the formed insulator layer has a top surface at the level lower than the top surface of the insulator layer above the source line. If, in this state, etching to form a portion to couple between the source line and an interconnect layer and etching to form a portion to couple between a contact and the interconnect layer are simultaneously conducted, the contact would be exposed too much. For this reason, in the comparative example, these etching processes are carried out as different steps. According to the embodiment as shown in FIG. 15, the insulator layer 47 and the semiconductor layer 302 in the locations corresponding to the memory cell array 10 and the region R1 are removed at the same time. Then, after formation of the source line SL, the space formed by the removal is filled with the insulator layer 44. Accordingly, as shown in FIG. 18, the trench SH1 corresponding to the coupling portion V1 and the multiple trenches SH2 corresponding to the multiple coupling portions V2 are concurrently formed. The manufacturing cost is therefore reduced.

### 2 Modifications

The foregoing embodiments may be modified in various ways. Semiconductor memory devices according to some of the modifications of the embodiments will be described.

### 2.1 First Modification

The foregoing embodiments have assumed a configuration in which the multiple coupling portions V2 are directly coupled to the multiple conductor layers 207, but this is not a limitation. The coupling portions V2 may be coupled to the multiple conductor layers 207 via a conductor layer or layers differing from the conductor layers 207. The description will basically concentrate on the particulars of a configuration and a manufacturing method of a semiconductor memory device 1 according to the first modification, which constitute differences from the configuration and the manufacturing method of the semiconductor memory device 1 according to the foregoing embodiments.

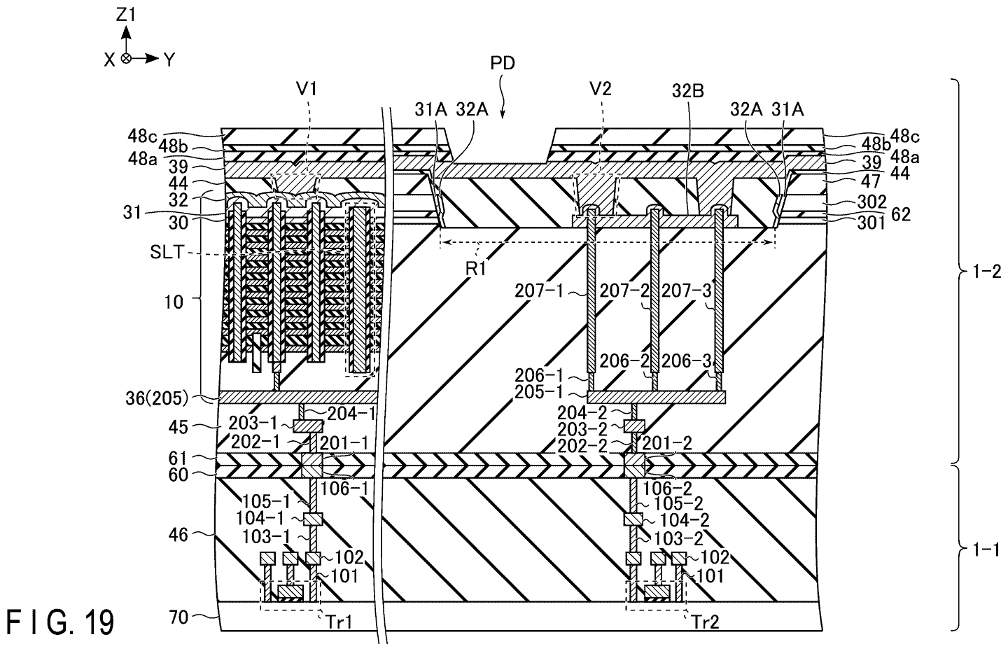

A configuration of the semiconductor memory device 1 according to the first modification will be described with reference to FIG. 19. FIG. 19 is a sectional view showing an exemplary sectional structure of a circuit region in the semiconductor memory device 1 according to the first modification.

As shown in FIG. 19, in the semiconductor memory device 1 according to the first modification, a conductor layer 32B is formed on the first surface of the insulator layer 45 in the region R1, in such a form that the conductor layer 32B covers the one-side portions of the multiple conductor layers 207. The conductor layer 32B has a plate shape extending over the X-Y plane. The first surface of the conductor layer 32B may have a dent and rise profile corresponding to the multiple conductor layers 207. That is, the conductor layer 32B may have a non-flat first surface. The first surface of the conductor layer 32B may instead be flat.

The first surface of the conductor layer 32B is in contact with the second surfaces of the multiple coupling portions V2. FIG. 19 shows an example where two of the coupling portions V2 are in contact with the conductor layer 32B. Here, the coupling portions V2 serve the purpose as long as they have an electrical connection with the conductor layer 32B, and they are not required to correspond to the multiple conductor layers 207. The coupling portions V2 may be provided in any number as long as it is one or more, and the number of the coupling portions V2 may equal or differ from the number of the conductor layers 207.

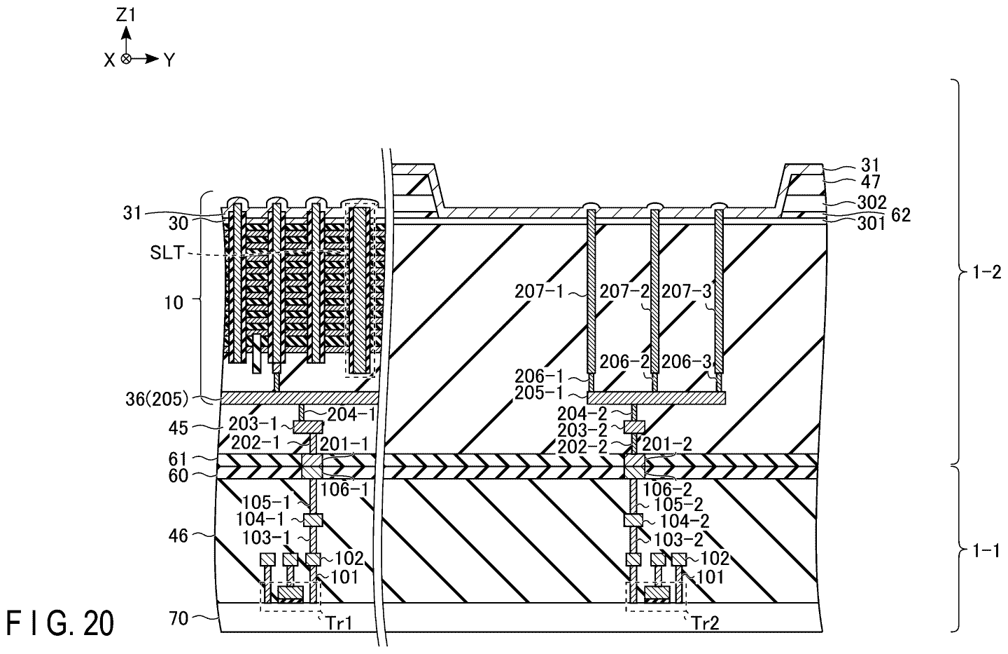

Next, a method for manufacturing the semiconductor memory device 1 according to the first modification will be described with reference to FIGS. 20 to 24. FIGS. 20 to 24 are sectional views for explaining an exemplary method for manufacturing the semiconductor memory device 1 according to the first modification. The sectional views shown in FIGS. 20 to 24 each show a part corresponding to FIG. 19.

First, steps similar to those explained with reference to FIGS. 12 to 15 for the foregoing embodiment are performed.

Then, as in the embodiment, a portion of the stacked film 52 that is located on the one side from the insulator layer 62 in each memory pillar MP is removed. As in the embodiment, the insulator layer 62 in the locations corresponding to the memory cell array 10 and the region R1 is removed.

Then, as shown in FIG. 20, the conductor layer 31 is stacked on the surface-exposed portions of the first surface of the semiconductor layer 301, the surface-exposed portions of the memory pillars MP, the first surface of the insulator layer 47, and the one-side portions of the multiple conductor layers 207. Also, as in the step in the embodiment described with reference to FIG. 16, a portion of the semiconductor layer 301 that corresponds to the memory cell array 10 is turned into the conductor layer 30 by diffusion of impurity.

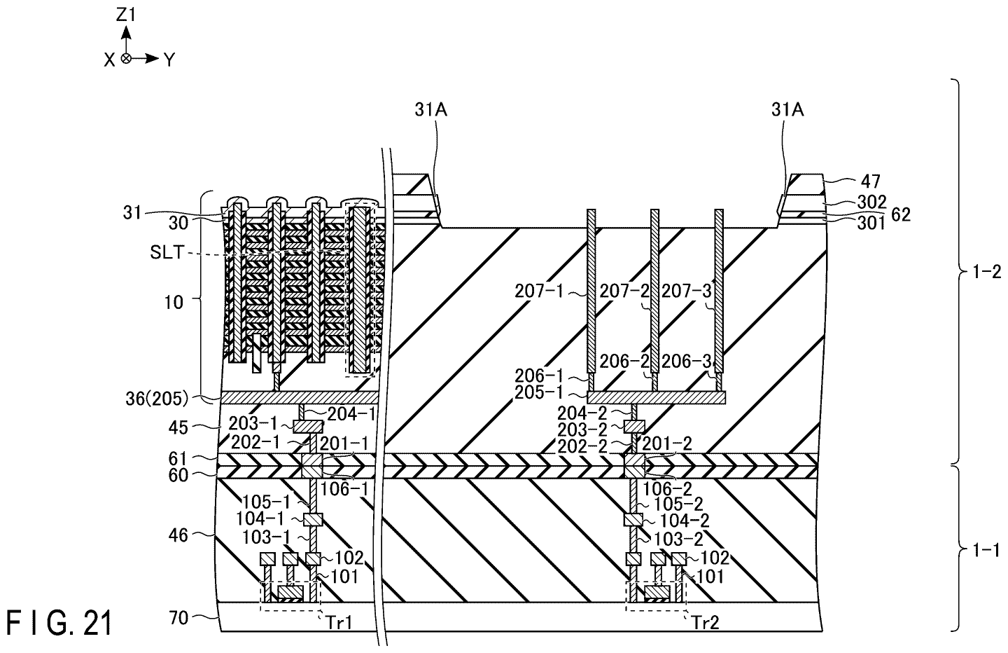

Then, as shown in FIG. 21, portions of the thus-formed conductor layer 31 that correspond to regions other than the memory cell array 10, and the portion of the semiconductor layer 301 that corresponds to the region R1 are removed. Accordingly, in the location corresponding to the region R1, a portion of the first surface of the insulator layer 45 and the respective one-side portions of the multiple conductor layers 207 are exposed. Here, in the location corresponding to the region R1, the one-side portion of the insulator layer 45 is also removed in addition to the conductor layer 31 and the semiconductor layer 301, for example. Also, as a result of the above process, the conductor layer 31A, which is a trace of the conductor layer 31, is formed on the wall surfaces constituted by the semiconductor layers 301 and 302 and the insulator layers 47 and 62 as shown in FIG. 21.

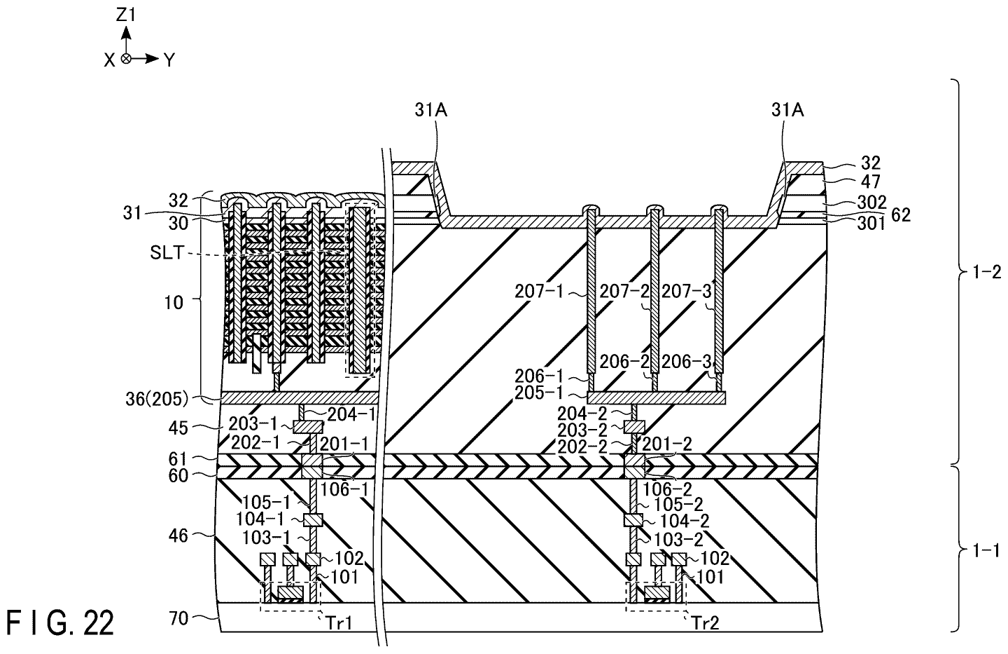

Subsequently, as shown in FIG. 22, the conductor layer 32 is stacked on the first surface of the conductor layer 31, the conductor layer 31A, the first surface of the insulator layer 47, the surface-exposed portion of the first surface of the insulator layer 45, and the one-side portions of the multiple conductor layers 207 that project from the insulator layer 45.

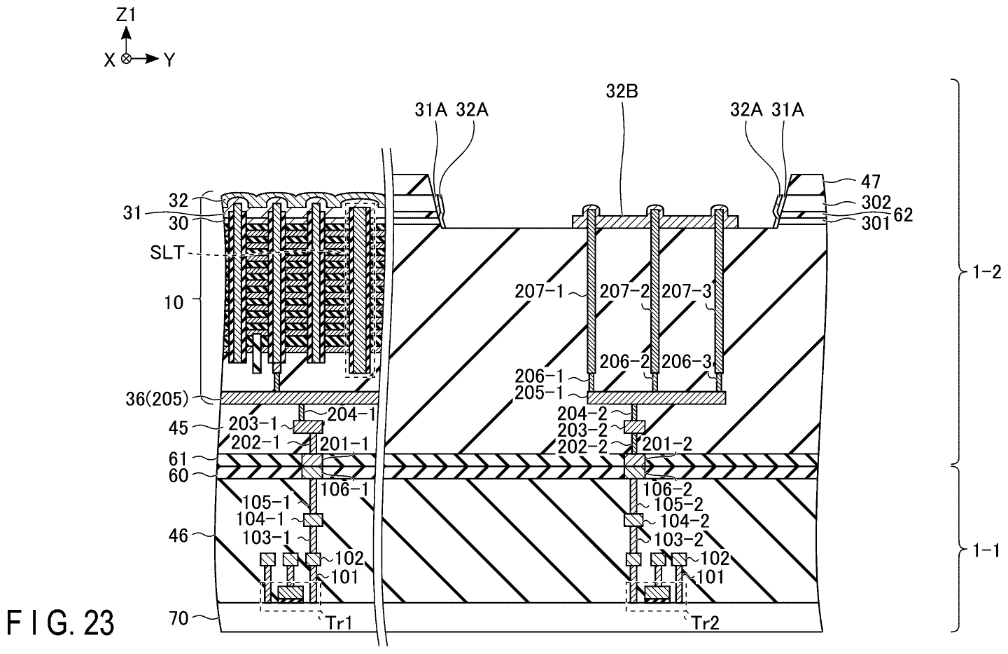

Then, as shown in FIG. 23, portions of the thus-formed conductor layer 32 other than regions that correspond to the memory cell array 10 and the conductor layer 32B are removed. The conductor layer 32 in the memory cell array 10, and the conductor layer 32B are thus formed. Also, as a result of the above process, the conductor layer 32A, which is a trace of the conductor layer 32, is formed on the wall surfaces constituted by the semiconductor layers 301 and 302 and the insulator layers 47 and 62 as shown in FIG. 23. Note that, also in this process, the one-side portion of the insulator layer 45 in the location corresponding to the region R1 may be removed as in the aforementioned process of removing the conductor layer 31 and the semiconductor layer 301 in the location corresponding to the region R1.

Then, the insulator layer 44 is formed as in the embodiment.

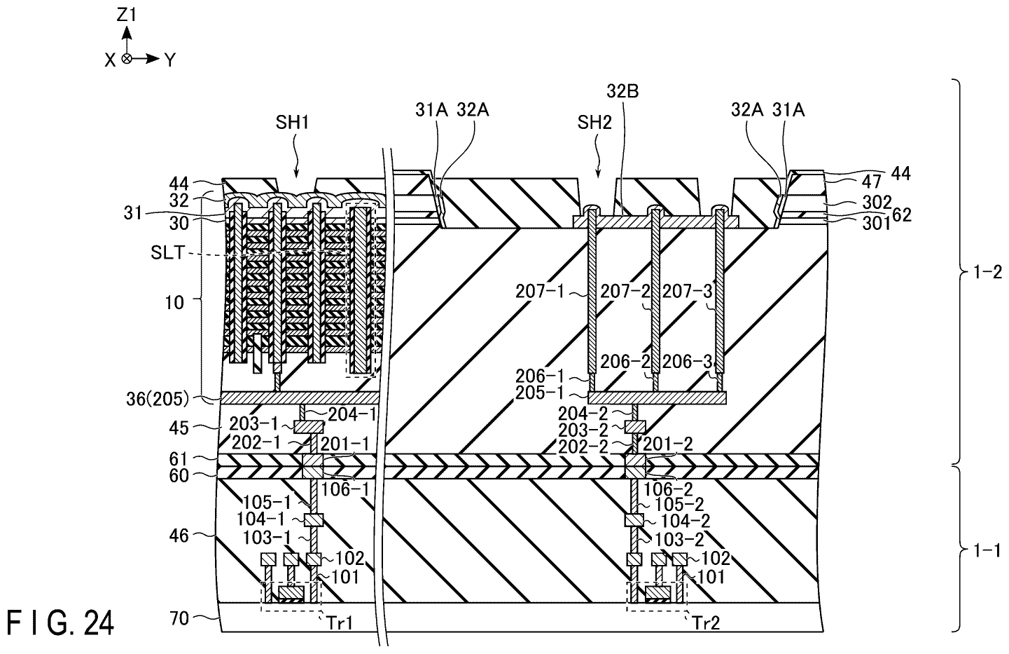

Subsequently, as shown in FIG. 24, the trench SH1 and the multiple trenches SH2 are concurrently formed as in the embodiment. Etching to form the trench SH1 and the multiple trenches SH2 is continued until the conductor layer 32B is exposed at the locations corresponding to the multiple trenches SH2.

Also, the conductor layer 39 and the insulator layers 48a, 48b, and 48c are formed as in the embodiment.

The semiconductor memory device 1 according to the first modification is formed through the manufacturing process as described above.

The first modification produces effects equivalent to those of the foregoing embodiments.

According to the first modification, additionally, the conductor layer 32B coupled to the multiple conductor layers 207 is provided. This allows the multiple coupling portions V2 to not necessarily correspond to the multiple conductor layers 207 as long as they have a connection to the conductor layer 32B. In other words, positions of the multiple coupling portions V2 do not need to be accurately aligned with the positions of the multiple conductor layers 207, respectively. Therefore, the cost of manufacturing the semiconductor memory device 1 can be reduced.

### 2.2 Second Modification

The foregoing embodiments have assumed a configuration in which the multiple coupling portions V2 are arranged in a grid pattern as shown in FIG. 10, but no limitations are intended by this. The description will basically concentrate on the particulars of a configuration of a semiconductor memory device 1 according to the second modification, which constitute differences from the configuration of the semiconductor memory device 1 according to the foregoing embodiments. Note that the method for manufacturing the semiconductor memory device 1 according to the second modification may be similar to the method for manufacturing the semiconductor memory device 1 according to the embodiments.

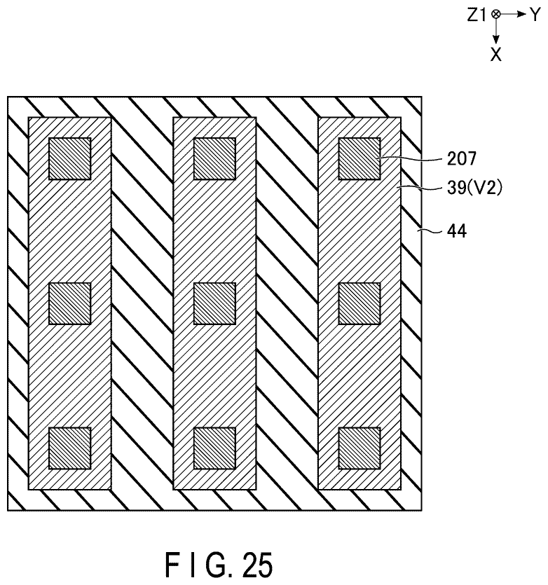

A configuration of the semiconductor memory device 1 according to the second modification will be described with reference to FIG. 25. FIG. 25 is a sectional view showing exemplary coupling portions between an interconnect layer and respective contacts in the semiconductor memory device 1 according to the second modification. FIG. 25 corresponds to the sectional view of the exemplary embodiment shown in FIG. 10.

As shown in FIG. 25, the multiple coupling portions V2 in the X-Y cross-section are each provided so as to extend in the X direction. In other words, the multiple coupling portions V2 are provided as multiple line structures arranged in the Y direction. In the X-Y cross section, the multiple coupling portions V2 may each be coupled to the multiple conductor layers 207 arranged in the X direction.

Such a second modification also produces effects equivalent to those of the foregoing embodiments.

### 2.3 Third Modification

The foregoing embodiments, the first modification, and the second modification have assumed a configuration in which the insulator layer 44 has a level difference near the boundary between the region R1 and its neighboring region, but this is not a limitation. The insulator layer 44 is not required to have a level difference near the boundary. The description will basically concentrate on the particulars of a configuration and a manufacturing method of a semiconductor memory device 1 according to the third modification, which constitute differences from the configuration and the manufacturing method of the semiconductor memory device 1 according to the foregoing embodiments.

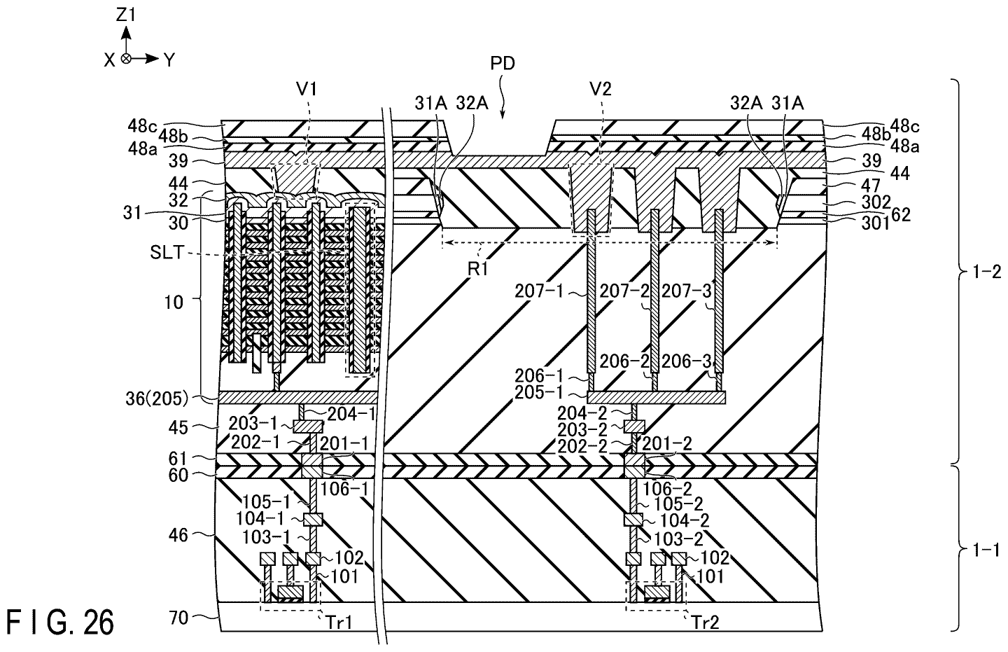

A configuration of the semiconductor memory device 1 according to the third modification will be described with reference to FIG. 26. FIG. 26 is a sectional view showing an exemplary sectional structure of a circuit region in the semiconductor memory device 1 according to the third modification.

As shown in FIG. 26, the first surface of the insulator layer 44 does not include a level difference near the boundary between the region R1 and a portion next to the region R1. Also, while not shown in FIG. 26, the first surface of the insulator layer 44 does not include a level difference near the boundary between the region where the conductor layer 32 is provided and its neighboring region.

The method for manufacturing the semiconductor memory device 1 according to the third modification may be similar to the method for manufacturing the semiconductor memory device 1 according to the embodiments except that, for the third modification, the method flattens the first surface of the insulator layer 44 at the time of conducting CMP to remove the portion of the insulator layer 44 that has been provided after the step explained with reference to FIG. 17 for the exemplary embodiment.

The third modification also produces effects equivalent to those of the foregoing embodiments.

### 3 Others

While certain embodiments have been described, these embodiments have been presented by way of example only, and are not intended to limit the scope of the inventions. Indeed, the novel embodiments described herein may be embodied in a variety of other forms. Furthermore, various omissions, substitutions, and changes in the form of the embodiments may be made without departing from the spirit of the inventions. The accompanying claims and their equivalents are intended to cover such forms or modifications as would fall within the scope and spirit of the inventions.

1. A semiconductor memory device comprising:
a first chip comprising a substrate defining a first region and a second region; and
a second chip contacting the first chip in a first direction crossing a surface of the substrate, the second chip being electrically connected to the first chip via a first connection pad at a boundary region between the first chip and the second chip,
the second chip comprising
a memory cell array in the first region, the memory cell array comprising a source line, a plurality of word lines mutually separated in the first direction below the source line, and a memory pillar extending in the first direction, crossing the word lines, and comprising an upper end coupled to the source line,
a first conductor in the second region, the first conductor extending in the first direction and electrically connected to the first connection pad, and
a first interconnect comprising a first coupling portion for electrical connection with an upper end of the first conductor, and a first extension continuously extending in a second direction crossing the first direction from an upper end of the first coupling portion and above an upper surface of the source line,
wherein
the first coupling portion has a shape in which a trench above the first conductor in the first direction is filled up to a level of a lower surface of the first extension in the first direction, and
the first coupling portion comprises a lower surface at a level below the upper surface of the source line in the first direction.

2. The semiconductor memory device according to claim 1, wherein the second chip further comprises
a pattern portion in the second region, the pattern portion being included in a same layer level as the source line, a part of the pattern portion that overlaps the first conductor in top view having been removed, and
a first insulator portion between the first coupling portion and the pattern portion,
wherein the lower surface of the first coupling portion is at a level below an upper surface of the pattern portion in the first direction.

3. The semiconductor memory device according to claim 2, wherein the first extension comprises a region exposed at an upper surface of the device and constituting an electrode pad.

4. The semiconductor memory device according to claim 3, wherein the electrode pad overlaps the first insulator portion in top view.

5. The semiconductor memory device according to claim 2, wherein the first extension comprises, in top view, a first sub-portion overlapping the pattern portion and a second sub-portion overlapping the first insulator portion,
the first sub-portion comprising a lower surface at a level higher than a lower surface of the second sub-portion.

6. The semiconductor memory device according to claim 2, wherein the first extension comprises, in top view, a first sub-portion overlapping the pattern portion and a second sub-portion overlapping the first insulator portion,
the lower surface of the first extension being flat throughout the first sub-portion and the second sub-portion.

7. The semiconductor memory device according to claim 1, wherein the second chip further comprises a second interconnect in the first region, the second interconnect comprising a second coupling portion contacting the upper surface of the source line and a second extension electrically connected to the source line via the second coupling portion and extending above the source line.

8. The semiconductor memory device according to claim 7, wherein the first coupling portion has a height in the first direction greater than a height in the first direction of the second coupling portion.

9. The semiconductor memory device according to claim 7, wherein the upper end of the first coupling portion and an upper end of the second coupling portion are aligned at a first level.

10. The semiconductor memory device according to claim 1, wherein the source line contains at least one of tungsten, aluminum, titanium, and/or titanium nitride.

11. The semiconductor memory device according to claim 10, wherein
the source line comprises a structure in which a plurality of conductor layers are laminated, and
an uppermost layer in the source line contains at least one of tungsten, aluminum, titanium, and/or titanium nitride.

12. The semiconductor memory device according to claim 1, wherein
the second chip further comprises a second conductor in the second region, the second conductor extending in the first direction and electrically connected to the first connection pad, and
the first interconnect further comprises a third coupling portion electrically connected to an upper end of the second conductor and comprising an upper end continuous with the first extension,
the third coupling portion having a shape in which a trench above the second conductor in the first direction is filled up to the level of the lower surface of the first extension in the first direction, and
the third coupling portion comprising a lower surface at a level below the upper surface of the source line in the first direction.

13. The semiconductor memory device according to claim 12, wherein
the second chip further comprises a third conductor in the second region, the third conductor extending in the first direction and electrically connected to the first connection pad, and
in a plane which crosses the first direction, a direction in which the first conductor and the second conductor are arranged and a direction in which the first conductor and the third conductor are arranged cross each other.

14. The semiconductor memory device according to claim 13, wherein the first interconnect further comprises a fourth coupling portion electrically connected to an upper end of the third conductor and comprising an upper end continuous with the first extension,
the fourth coupling portion having a shape in which a trench above the third conductor in the first direction is filled up to the level of the lower surface of the first extension in the first direction, and
the fourth coupling portion comprising a lower surface at a level below the upper surface of the source line in the first direction.

15. The semiconductor memory device according to claim 13, wherein the first coupling portion is electrically connected to an upper end of the third conductor in addition to the upper end of the first conductor,
the first coupling portion being a linear structure in top view.

16. The semiconductor memory device according to claim 1, wherein the second chip further comprises a fourth conductor contacting each of the upper end of the first conductor and a lower end of the first coupling portion,
the first conductor and the first coupling portion being coupled via the fourth conductor.

17. The semiconductor memory device according to claim 16, wherein the fourth conductor contains at least one of tungsten, aluminum, titanium, and/or titanium nitride.

18. The semiconductor memory device according to claim 1, wherein an aspect ratio obtained by dividing a height of the first coupling portion by a width of the first coupling portion in a direction crossing the first direction is 1.5 or less.

19. The semiconductor memory device according to claim 1, wherein the upper surface of the source line has a dent and rise profile.

20. The semiconductor memory device according to claim 2, wherein the second chip further comprises a fifth conductor between the pattern portion and the first insulator portion.
